(19) United States
(12) Patent Application Publication
(10) Pub. No.: US 2025/0291962 A1
(43) Pub. Date: Sep. 18, 2025

(54) SYNCHRONOUS OPTIMIZATION WORKFLOW TO SUPPORT EFFICIENT DESIGN AND/OR MANUFACTURE OF REINFORCED CONCRETE COLUMNS

(71) Applicant: The Texas A&M University System, College Station, TX (US)

(72) Inventors: Cesario Tavares, Bryan, TX (US); Kinsey Skillen, College Station, TX (US); Zachary Grasley, College Station, TX (US)

(73) Assignee: The Texas A&M University System, College Station, TX (US)

(21) Appl. No.: 19/082,705

(22) Filed: Mar. 18, 2025

Related U.S. Application Data
(60) Provisional application No. 63/566,602, filed on Mar. 18, 2024.

(51) Int. Cl. G06F 30/13

(52) U.S. Cl. CPC G06F 30/13

(57) ABSTRACT

A method for designing and fabricating structural components, comprising loading one or more instructions into a data memory device of a processor that cause the processor to perform the steps of generating a gross area limit metric and a gross area minimum metric for predetermined boundary conditions, generating a gross area short metric and a gross area long metric for a plurality of available materials, setting the gross area minimum metric to the gross area short metric if it is determined that the gross area short metric is not greater than the gross area minimum metric and fabricating a structural component using the gross area minimum metric.

### RELATED APPLICATIONS

This application claims benefit of and priority to U.S. Provisional patent application 63/566,602, filed Mar. 18, 2024, which is hereby incorporated by reference for all purposes as if set forth herein in its entirety.

### TECHNICAL FIELD

The present disclosure relates generally to fabricated structural components, and more specifically to systems and methods for designing and/or manufacturing structural components.

### BACKGROUND OF THE INVENTION

Design of structural systems and associated structural components typically does not entail metrics to mitigate environmental impacts, due to the complexity and importance of the structural design process and corresponding safety parameters.

### SUMMARY OF THE INVENTION

A method for optimizing the design and/or manufacture of structural components is disclosed that includes loading one or more instructions into a data memory device of a processor that cause the processor to perform the steps of generating a gross area limit metric and a gross area minimum metric for predetermined boundary conditions, generating a gross area short metric and a gross area long metric for a plurality of available materials, setting the gross area minimum metric to the gross area short metric if it is determined that the gross area short metric is not greater than the gross area minimum metric and fabricating a structural component using the gross area minimum metric.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings may be to scale, but emphasis is placed upon clearly illustrating the principles of the present disclosure. Moreover, in the drawings, like reference numerals designate corresponding parts throughout the several views, and in which:

FIG. 1 is a diagram of a system for incorporating cost and environmental parameters into a structural design process, in accordance with an example embodiment of the present disclosure;

FIG. 2 is a diagram of an algorithm for incorporating cost and environmental parameters into a structural design process, in accordance with an example embodiment of the present disclosure;

FIG. 3 is a diagram of a 12-story RC office building, in accordance with an example embodiment of the present disclosure;

FIGS. 4A-4D are diagrams of graphs of the results for interior columns placed on the first floor when cast with mix NSC-7;

FIGS. 5A-5B are charts showing the contributions from concrete mix, longitudinal steel reinforcement and shear reinforcement to the total embodied CO₂ of interior columns placed on the first floor of the RC building;

FIG. 6 is a diagram showing the results for the example embodiments listed in Table 4, as well as all column types listed in Table 6;

FIGS. 7A-7B are diagrams showing correlations between the material's volumetric embodied CO₂ versus the total CO₂ produced to cast all columns, in accordance with an example embodiment of the present disclosure;

FIG. 8 is a diagram that can be used to assess cost-efficiency of different concrete types in RC columns using the correlation between unit cost of concrete mix versus total cost of RC columns at two different reinforcement levels, in accordance with an example embodiment of the present disclosure; and

FIGS. 9A-9B are diagrams that summarizes an optimum design solution, in accordance with an example embodiment of the present disclosure.

### DETAILED DESCRIPTION OF THE INVENTION

In the description that follows, like parts are marked throughout the specification and drawings with the same reference numerals. The drawing figures may be to scale and certain components can be shown in generalized or schematic form and identified by commercial designations in the interest of clarity and conciseness.

The present disclosure provides design workflow systems and algorithms for designing and fabricating structural components, such as reinforced concrete (RC) columns or other suitable structural components, that conjointly optimizes cost and environmental impacts. Adjustments to the ACI 318-19 design provisions are recommended to include the disclosed systems and methods to help fabricate structural components with the best combination of materials and column geometries to produce the most cost-effective and eco-friendly structures. To demonstrate the disclosed systems and methods, different column shapes, concrete mixtures, reinforcement ratios and steel-reinforcement manufacturing routes are used to model RC columns for a 12-story building, but other suitable applications can also or alternatively be used. To be clear, while the present disclosure uses columns as an example, it is not limited to columns or any other specific structural elements, and can be applied to walls, load bearing elements and other suitable structural or non-structural elements. Wherever columns are discussed herein, it will be understood that other suitable structural elements could also or alternatively be used.

The present disclosure incorporates by reference all materials from U.S. Provisional patent application 63/566,602, filed Mar. 18, 2024, for all purposes as if set forth herein in its entirety, including but not limited to all appendices.

None of the materials provided herein or incorporated by reference are an admission of prior art, and to the extent that information regarding current practices or conventional methods is provided, it is selected from general background information in order to demonstrate the differences between those current practices or conventional methods and the present disclosure, as well as presented in a format to provide support for excerpts of the present disclosure, such that the present disclosure can be understood to be inventive by its identification of specific orders and combinations of new and prior art materials, even though it includes selected portions of those prior art materials.

The present disclosure provides a design workflow for reinforced concrete (RC) columns or other suitable structural elements that conjointly optimizes cost and environmental impacts. Adjustments to the American Concrete Institute (ACI) code 318-19 design provisions or other suitable standards can be made as discussed herein to include this workflow in conceptual stages of design to help select the best combination of materials and column geometries that produces the most cost-effective and eco-friendly designs. To utilize this workflow, different column shapes, concrete mixtures, reinforcement ratios and steel-reinforcement manufacturing routes are used to optimize the design of RC columns. As further discussed herein, 1) decreasing reinforcing-steel content and embodied carbon footprint of materials on a per-unit-volume basis does not minimize the total carbon footprint of RC columns; 2) the contribution of steel reinforcement to the total carbon footprint of RC columns can, at times, increase the contribution of concrete by a factor of three; and 3) eco-efficiency of RC columns is poorly correlated with binder content and concrete technologies.

Cement and concrete demands are projected to increase over the next two decades. Global population growth is likely to accentuate the existing housing deficit and the need for new, resilient and reliable functioning infrastructure. Meanwhile, rising levels of greenhouse gas (GHG) emissions require a 50-to-85% reduction in these emissions by 2050 to prevent threatening climate changes. While many strategies have been delineated to reduce GHG emissions from the cement and concrete industry, optimization of structural design efficiency as a function of material properties has not been utilized in the prior art.

Concrete mix proportioning and structural design optimization have been mostly addressed as two separate challenges rather than a joint optimization problem. There is a lack of tools and methods capable of integrating both design domains to maximize the efficiency of RC structures. As evidence, global warming potential (GWP) remains the primary indicator used to compare environmental impacts associated with using different concretes in a given structure. GWP is typically reported by concrete producers in environmental product declarations (EPD) in units of mass of carbon dioxide (CO₂) equivalent (CO₂-eq) per unit volume of concrete (e.g., kg.CO₂-eq/m³). The present disclosure recognizes that this metric alone cannot account for the effects of changes in mechanical performance, as a function of concrete mix proportioning, in dictating the dimensionality—and thus volume of concrete and steel—of structural members and their resulting carbon footprint.

Metrics that account for environmental impacts and mechanical performance driving structural design of reinforced concrete members have practical limitations. For instance, the area and strength of reinforcing-steel bars (commonly referred to as “rebars” in the construction industry) were kept constant when comparing different concrete formulations, which inhibits proper quantification of the effects of changes in steel reinforcement on the overall environmental impact of a given structural member. This constraint is particularly important for modern concretes (e.g., with very high strengths) where, for certain applications, less reinforcement is required due to the reduced size of the cast members. In addition, the presence of discontinuous fibers can also reduce the required shear reinforcement.

The present disclosure provides modifications to the ACI 318-19 structural design provisions related to the design of steel reinforced concrete (RC) columns to accommodate for cost and environmental considerations prior to reinforcement detailing. The disclosed workflow allows selection of the combination of concrete mixture, column shape, cross-sectional area and reinforcement ratio that will produce the RC columns with the lowest cost and embodied carbon footprint while satisfying structural capacity constraints. The workflow includes cost and environmental impact quantifiers that generate the concurrent effects of mix proportions and mechanical properties in dictating column sizing and reinforcement. The workflow further evaluates cost and environmental impacts resulting from different concrete mixtures at early stages of design (conceptual phase), as well as at final stages (post structural analysis) to refine material selection. As such, the workflow promotes an effective use of concrete and steel that minimizes the total carbon footprint and cost of RC buildings.

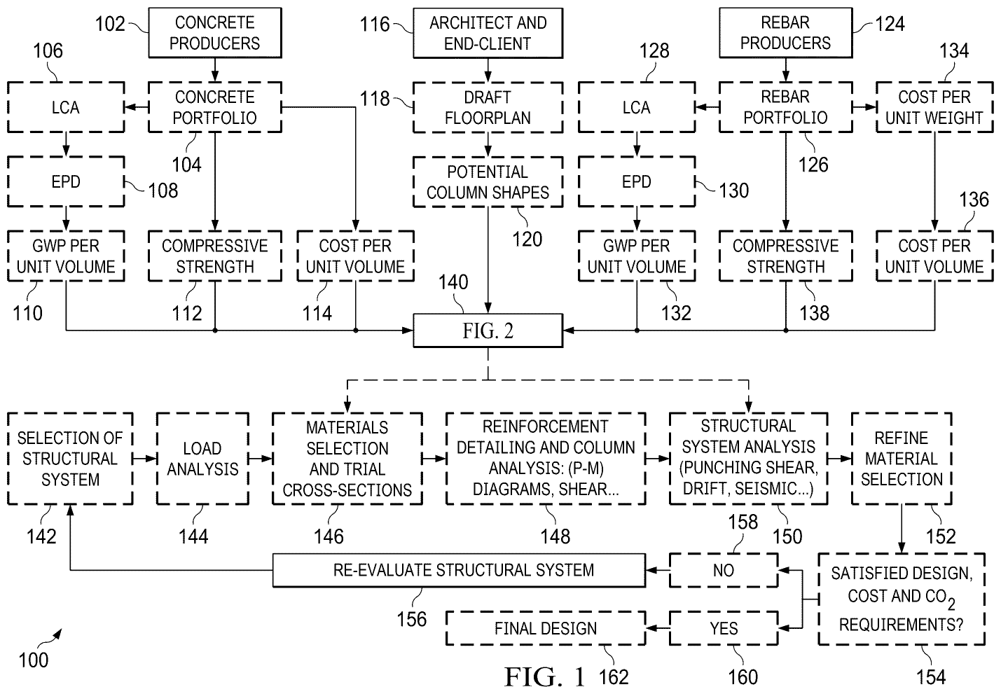

FIG. 1 is a diagram of a system 100 for incorporating cost and environmental parameters into a structural design and/or manufacture process, in accordance with an example embodiment of the present disclosure. System 100 can be implemented in hardware or a suitable combination of hardware and software. The connections and arrows shown in system 100 can be implemented as data communications processes utilizing suitable network data communications and can be bi-directional as needed to facilitate interoperability. Likewise, the subsystems components of system 100 can interact over a network with other subsystem components, where suitable and as further described herein.

System 100 includes stages where this workflow can be incorporated in a design process to deliver cost and environmental recommendations. In this example embodiment, the costs and CO₂ emissions associated with using 3 different concrete technologies to cast RC columns are evaluated for a low-rise building, but other suitable variations can also or alternatively be used. Information on mix proportions, compressive strengths, unit costs and GWP factors for 30 concrete formulations can be obtained from various studies in the literature to perform the analysis. This information can then be used to assess the efficacy of the proposed method at conceptual stages of design to facilitate material and shape selection while designing RC columns according to ACI 318-19 provisions, or for other suitable purposes.

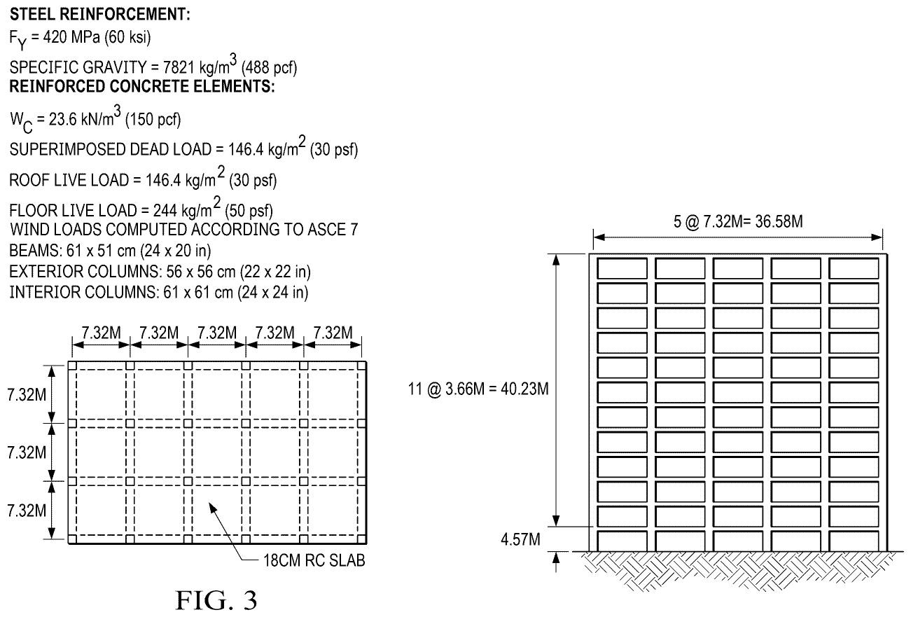

Concrete producers system 102 can be implemented as one or more lines of code that are loaded into a working memory of a processor and which configure the processor to identify concrete producers, as discussed and described in greater detail herein, such as in the discussion of FIGS. 3-9. Concrete producers system 102 generates data output for use by concrete portfolio system 104, as discussed herein.

Concrete portfolio system 104 can be implemented as one or more lines of code that are loaded into a working memory of a processor and which configure the processor to identify concrete portfolios, as discussed and described in greater detail herein, such as in the discussion of FIGS. 3-9. Concrete portfolio system 104 generates data output for use by life cycle assessment system 106, compressive strength system 112 and cost per unit volume system 114, as discussed herein.

Life cycle assessment system 106 can be implemented as one or more lines of code that are loaded into a working memory of a processor and which configure the processor to perform a life cycle assessment, as discussed and described in greater detail herein, such as in the discussion of FIGS. 3-9. Life cycle assessment system 106 generates data output for use by environmental product declaration system 108, as discussed herein.

Environmental product declaration system 108 can be implemented as one or more lines of code that are loaded into a working memory of a processor and which configure the processor to identify an environmental product declaration, as discussed and described in greater detail herein, such as in the discussion of FIGS. 3-9. Environmental product declaration system 108 generates data output for use by global warming potential per unit volume system 110, as discussed herein.

Global warming potential per unit volume system 110 can be implemented as one or more lines of code that are loaded into a working memory of a processor and which configure the processor to identify global warming potential per unit volume, as discussed and described in greater detail herein, such as in the discussion of FIGS. 3-9. Global warming potential per unit volume system 110 generates data output for use by system 200, as discussed herein.

Compressive strength system 112 can be implemented as one or more lines of code that are loaded into a working memory of a processor and which configure the processor to assess structural component strength, as discussed and described in greater detail herein, such as in the discussion of FIGS. 3-9. Compressive strength system 112 generates data output for use by system 200, as discussed herein.

Cost per unit volume system 114 can be implemented as one or more lines of code that are loaded into a working memory of a processor and which configure the processor to identify a cost per unit volume, as discussed and described herein, such as in the discussion of FIGS. 3-9. Cost per unit volume system 114 generates data output for use by system 200, as discussed herein.

Architect and end client system 116 can be implemented as one or more lines of code that are loaded into a working memory of a processor and which configure the processor to receive data from an architect and end client, as discussed and described herein, such as in the discussion of FIGS. 3-9. Architect and end client system 116 generates data output for use by draft floor plan system 118, as discussed herein.

Draft floor plan system 118 can be implemented as one or more lines of code that are loaded into a working memory of a processor and which configure the processor to receive a draft floor plan, as discussed and described herein, such as in the discussion of FIGS. 3-9. Draft floor plan system 118 generates data output for use by potential column shapes system 120, as discussed herein.

Potential column shapes system 120 can be implemented as one or more lines of code that are loaded into a working memory of a processor and which configure the processor to generate potential column shapes, as discussed and described herein, such as in the discussion of FIGS. 3-9. Potential column shapes system 120 generates data output for use by system 200, as discussed herein.

Rebar producers 124 system can be implemented as one or more lines of code that are loaded into a working memory of a processor and which configure the processor to identify rebar producers, as discussed and described herein, such as in the discussion of FIGS. 3-9. Rebar producers 124 generates data output for use by rebar portfolio system 126, as discussed herein.

Rebar portfolio system 126 can be implemented as one or more lines of code that are loaded into a working memory of a processor and which configure the processor to identify a rebar portfolio, as discussed and described herein, such as in the discussion of FIGS. 3-9. Rebar portfolio system 126 generates data output for use by life cycle assessment system 128, compressive strength system 138 and cost per unit weight system 134, as discussed herein.

Life cycle assessment system 128 can be implemented as one or more lines of code that are loaded into a working memory of a processor and which configure the processor to perform a life cycle assessment, as discussed and described herein, such as in the discussion of FIGS. 3-9. Life cycle assessment system 128 generates data output for use by environmental product declaration system 130, as discussed herein.

Environmental product declaration system 130 can be implemented as one or more lines of code that are loaded into a working memory of a processor and which configure the processor to identify an environmental product declaration, as discussed and described herein, such as in the discussion of FIGS. 3-9. Environmental product declaration system 130 generates data output for use by global warming potential per unit volume system 132, as discussed herein.

Global warming potential per unit volume system 132 can be implemented as one or more lines of code that are loaded into a working memory of a processor and which configure the processor to assess global warming potential per unit volume, as discussed and described herein, such as in the discussion of FIGS. 3-9. Global warming potential per unit volume system 132 generates data output for use by system 200, as discussed herein.

Cost per unit weight system 134 can be implemented as one or more lines of code that are loaded into a working memory of a processor and which configure the processor to determine a cost per unit weight, as discussed and described herein, such as in the discussion of FIGS. 3-9. Cost per unit weight system 134 generates data output for use by cost per unit volume system 136, as discussed herein.

Cost per unit volume system 136 can be implemented as one or more lines of code that are loaded into a working memory of a processor and which configure the processor to determine a cost per unit volume, as discussed and described herein, such as in the discussion of FIGS. 3-9. Cost per unit weight system 134 generates data output for use by system 200, as discussed herein.

Compressive strength system 138 can be implemented as one or more lines of code that are loaded into a working memory of a processor and which configure the processor to determine compressive strength, as discussed and described herein, such as in the discussion of FIGS. 3-9. Compressive strength system 138 generates data output for use by system 200, as discussed herein.

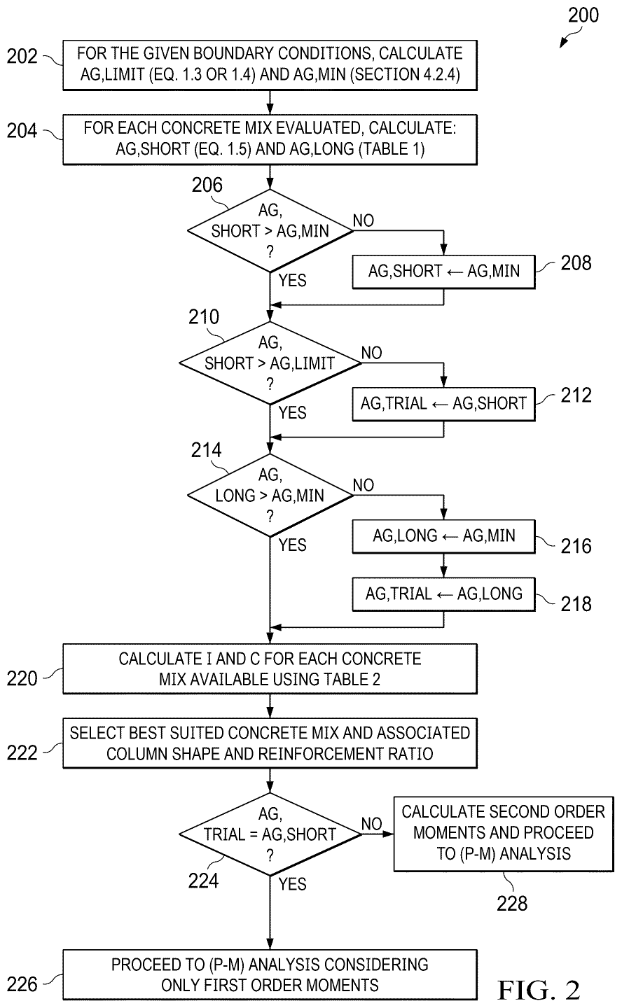

System 200 can be implemented as one or more lines of code that are loaded into a working memory of a processor and which configure the processor to generate data and perform functions described in greater detail in FIG. 2, as discussed and described in greater detail herein, such as in the discussion of FIGS. 3-9.

Selection of structural system 142 can be implemented as one or more lines of code that are loaded into a working memory of a processor and which configure the processor to select a structural system, as discussed and described herein, such as in the discussion of FIGS. 3-9. Selection of structural system 142 receives data from re-evaluate structural system 156 and generates data output for use by load analysis system 144, as discussed herein.

Load analysis system 144 can be implemented as one or more lines of code that are loaded into a working memory of a processor and which configure the processor to perform a load analysis, as discussed and described herein, such as in the discussion of FIGS. 3-9. Load analysis system 144 receives data from selection of structural system 142 and generates data output for use by materials selection and trial cross sections system 146, as discussed herein.

Materials selection and trial cross sections system 146 can be implemented as one or more lines of code that are loaded into a working memory of a processor and which configure the processor to identify materials selection and trial cross sections, as discussed and described herein, such as in the discussion of FIGS. 3-9. Materials selection and trial cross sections system 146 receives data from load analysis system 144 and system 200 generates data output for use by reinforcement detailing and column analysis: (P-M) diagrams and shear system 148, as discussed herein.

Reinforcement detailing and column analysis: (P-M) diagrams and shear system 148 can be implemented as one or more lines of code that are loaded into a working memory of a processor and which configure the processor to generate reinforcement detailing and column analysis for (P-M) diagrams and shear, as discussed and described herein, such as in the discussion of FIGS. 3-9. Reinforcement detailing and column analysis: (P-M) diagrams and shear system 148 receives data from materials selection and trial cross sections system 146 and generates data output for use by structural systems analysis (punching, shear, drift, seismic) system 150, as discussed herein.

Structural systems analysis (punching, shear, drift, seismic) system 150 can be implemented as one or more lines of code that are loaded into a working memory of a processor and which configure the processor to generate structural systems analysis (punching, shear, drift, seismic), as discussed and described herein, such as in the discussion of FIGS. 3-9. Structural systems analysis (punching, shear, drift, seismic) system 150 receives data from reinforcement detailing and column analysis: (P-M) diagrams and shear system 148 and generates data output for use by refined material selection system 152, as discussed herein.

Refined material selection system 152 can be implemented as one or more lines of code that are loaded into a working memory of a processor and which configure the processor to generate refined materials selection, as discussed and described herein, such as in the discussion of FIGS. 3-9. Refined material selection system 152 receives data from structural systems analysis (punching, shear, drift, seismic) system 150 and system 200 and generates data output for use by satisfied design and/or manufacture cost and CO₂ requirements 154, as discussed herein.

Satisfied design and/or manufacture cost and CO₂ requirements 154 can be implemented as one or more lines of code that are loaded into a working memory of a processor and which configure the processor to generate a design and/or manufacture cost and CO₂ requirements analysis for (P-M) diagrams and shear, as discussed and described herein, such as in the discussion of FIGS. 3-9. Satisfied design and/or manufacture cost and CO₂ requirements 154 receives data from refine materials selection system 152 and generates data output for use at 158 and 160.

Reevaluate structural system 156 can be implemented as one or more lines of code that are loaded into a working memory of a processor and which configure the processor to reevaluate the system, as discussed and described herein, such as in the discussion of FIGS. 3-9. Reevaluate structural system 156 receives data from 158 and generates output data for selection of structural system 142.

At 158, if it is determined that the design and/or manufacture cost and CO₂ requirements are not met, the process returns to re-evaluate structural systems 156, as discussed and described herein, such as in the discussion of FIGS. 3-9.

At 160, if it is determined that the design and/or manufacture cost and CO₂ requirements are met, the process proceeds to 162, as discussed and described herein, such as in the discussion of FIGS. 3-9.

Final design and/or manufacture system 162 can be implemented as one or more lines of code that are loaded into a working memory of a processor and which configure the processor to receive data from 160 and to generate a final design and/or manufacture, as discussed and described herein, such as in the discussion of FIGS. 3-9.

In operation, system 100 can identify and incorporate cost and environmental parameters for a structural design and/or manufacturing process, such as by providing an architecture for integration of data from critical sources for the purpose of designing structures that can be built with reduced environmental impact while still meeting structural requirements and based on the overall design and not a single metric for one material used in the design.

System 100 provides an effective methodology to support decarbonization of RC structures during design stages, by utilizing concurrent optimization of concrete and steel while synergistically driving proportioning of RC structures. Reinforcement layout and concrete properties have a combined effect in optimizing the dimensionality of structural elements and, consequently, optimizing the cost and carbon footprint of an entire building. Current design provisions can be adjusted to incorporate environmental considerations, leading to a more informed quantification of environmental impacts associated with entire projects. While focused on column design in RC structures, system 100 can be modified for the development of other structural elements.

Concrete consumption continues to grow at a rate comparable to global population growth, with cement and steel leading as the most carbon intensive components of RC structures. In 2010, cement and steel production collectively accounted for 61% of the 7.7 gigatonnes (Gt) of CO₂ released globally by the construction industry. Currently, cement production is responsible for 9% of global GHG emissions, similar to what is estimated for steel production. To address this issue, strategies to relieve the environmental burden from cement and concrete production can be utilized.

In the field of structural design, computational tools that perform detailed optimization of RC structures have evolved over the years, with material usage and cost efficiency often providing the objective function. From the various tools and techniques adopted to solve the structural design optimization problem, formulation of objective functions has been mostly centered around the minimization of steel reinforcement and concrete consumption and overall weight of RC structures to reduce overall structural costs. Meanwhile, tools to minimize costs associated with formwork, labor, transportation, waste rate of reinforcing bars, material fabrication and installation have also been developed. Recently, global awareness on GHG emissions and depletion of natural resources have fostered the development of tools focused on environmental impact mitigation, with features that help minimize concrete and steel demands.

Due to the complex interaction between the optimization of individual structural members and their topological arrangement within RC structures, most computational tools perform the required iterations while assigning one concrete grade for the entire structure. At best, different concrete grades can be assigned to different structural elements. However, when various concrete mixtures and reinforcement types are to be considered for an RC structure, a detailed structural design is often needed for each set of materials under consideration. This is not an ideal scenario for engineering firms considering the extensive computational time and personnel resources required to perform these tasks on a recurring basis.

From the cement industry perspective, decarbonization of the manufacturing process has been a focus of research. Efforts to electrify the heating process or achieve electrochemical synthesis of lime during the calcination are promising and impactful methods, where a 75% reduction in CO₂ emissions has reportedly been achieved. However, scalability is a major challenge if the technology would require replacing major equipment in existing cement plants, which is unlikely to be accomplished in the next decade given the “risk-averse” nature of the construction industry. Other solutions involving calcium sulfoaluminate cements, carbon capture and storage, or alkali-activated cements could evolve in the long run, but these technologies are also unlikely to be implemented in a timely manner at the global scale to help achieve environmental goals of 2050.

The present disclosure recognizes that marginal cumulative gains from readily implementable strategies could help achieve significant reductions in GHG emissions. Examples are: 1) optimizing clinker production with more energy-efficient kilns and fuels; 2) optimizing the efficiency of cement production with partial replacement of clinker (e.g., calcined clay limestone cement (LC3) or portland limestone cement (PLC); 3) improving efficiency of cement use in concrete through partial replacement with supplementary cementitious materials (SCMs) and efficient aggregate gradations; 4) improving construction efficiency by minimizing waste; and 5) improving structural design efficiency to minimize volume of material used in structures. The disjointed nature of the construction industry, with multiple stakeholders acting independently, is preventing these mitigation strategies from being implemented in a unified and efficient way. For instance, carbon savings obtained from reducing the GWP of a concrete mixture on a per volume basis are meaningless if the intended structure is designed with more volume of material than required for the intended application resulting in an overall larger GHG footprint of the final structure.

Concrete strengths made significant strides in the 1980s with the emergence of high-range water reducers (HRWR) and new understanding of the role of aggregates and mineral admixtures on concrete microstructures. HRWR, also known as superplasticizers, improve the workability of fresh concrete while allowing substantial reductions in the water-to-cementitious materials ratio (w/cm). The combination of low w/cm and careful aggregate selection (with maximum sizes typically up to 14 mm) led to the development of concrete formulations with compressive strength ranging from 55 MPa (8,000 psi) and 120 MPa (17,500 psi) classified as high-strength concretes (HSC). Currently, HSC is a subset of high-performance concretes (HPC) which, in addition to high compressive strength, show enhanced durability.

One of the main applications of HSC is for columns placed in lower stories of mid-rise and high-rise RC buildings, which are subjected to very high axial loads. In small buildings, one grade of concrete is typically used throughout the entire structure, with strengths ranging between 25-30 MPa (4000-4500 psi). In tall buildings, HSC allows RC columns to be built with reduced dimensions, opening more floor space while reducing material costs. When using columns with strengths considerably higher than the grade used in the floor, designers make proper considerations regarding the load transfer through the weaker floor concrete. In addition, concerns regarding the occurrence of explosive spalling when HSC is subjected to fire requires appropriate considerations; this is due to the brittleness of HSC, which can result in non-ductile RC columns in the absence of an appropriate amount of steel confinement. In fact, ACI building code 318-19 has stricter reinforcement requirements for HSC than for NSC. Nevertheless, the addition of steel fibers has shown to be an effective method to prevent brittle failure of HSC columns, by improving their ductility, crack and spalling control, impact resistance and confinement.

The need for more resilient, compact, and long-lasting structures drove further advances in concrete materials in pursuit of superior mechanical and durability properties. Design principles fundamentally based on increased particle packing density, enhanced homogeneity of concrete microstructures and very low w/cm propelled the development of a new class of cementitious composites known as ultra-high-performance concrete (UHPC). This definition is typically reserved for concretes with compressive strengths over 150 MPa (22,000 psi), with specified tensile ductility, durability, and toughness requirements. The advanced properties of UHPC enable the design of more efficient structural elements with lesser volumes of concrete compared to NSC and HPC, while also requiring less maintenance costs due to its exceptional durability. Moreover, steel fibers used in UHPC allow partial (or at times, full) replacement of transverse steel reinforcement. The use of UHPC continues to expand to larger structural elements. Recent experimental studies on seismic UHPC columns have shown that 40% reduction in cross-sectional area can be attained with UHPC in lieu of conventional RC columns while maintaining comparable ductility. These results motivate further investigation on the costs and environmental impacts associated with RC columns built with different concrete technologies (e.g., NSC, HSC, UHPC) for various types of buildings (from low-rise to skyscrapers).

A brief synopsis of the disclosed workflow to design RC columns that have improved environmental parameters and that are in accordance with the ACI 318-19 Building Code Requirements is provided. The design process typically initiates with one of two possible scenarios: 1) the cross-sectional area and steel reinforcement are known (e.g., column size suggested by architect) and a section analysis is carried out to compute capacity or; 2) a cross-section is chosen a priori by the structural engineer based on experience or similar, previous projects and designed (analyzed, revised, reanalyzed) to resist estimated factored loads and moments. The choice of column type is a function of the efficiency achieved for the selected shape and reinforcement placed to resist a given load configuration. For instance, for eccentricity ratios (e/h) over 0.2, rectangular columns with bars located in the faces farthest from the bending axis are typically more efficient than circular columns, where the bars are equally spaced around the perimeter. Conversely for low eccentricity ratios (e/h<0.1), spiral circular columns tend to be more efficient in terms of load capacity than squared/rectangular tied columns due to a higher strength reduction factor allowed to account for the confinement effect provided by spirals. However, increased costs of column forming and spiral reinforcement may at times offset the cost benefit of smaller cross sections.

In cases where shape and dimensions are not explicitly defined by the architectural concept, the design process typically initiates with the structural designer estimating the required size of the column. In this iteration, the size is initially assumed to be governed by the maximum nominal axial load capacity, ϕP_{n,max}, and later analyzed for shear, bending moments, and eventually torsion (less common), during reinforcement detailing. For tied columns, this expression is given by

$$ϕ {P}_{n , max} \leq 0.8 ϕ [ 0.85 {f}_{c}^{′} {A}_{c} + {f}_{y} {A}_{st} ] , \qquad ( 1.1 )$$

where the strength reduction factor ϕ is equal to 0.65, f′_{c} is the specified compressive strength, A_{c} is the effective area of concrete, f_{y} is the specified yield strength for nonprestressed steel reinforcement and Aₛₜ is the area of longitudinal steel reinforcement. For spiral columns, the term 0.8ϕ is replaced by 0.85ϕ while ϕ is equal to 0.75 instead. To define the trial area for analysis, equation (1.1) can be rearranged to express this area as a function of load demands and material properties. For tied columns,

$$A \text{?} \geq \frac{P \text{?}}{0.4 ( {f}_{c}^{′} + {f}_{y} {ρ}_{w} )} , \qquad ( 1.2 )$$

$$\text{?} \text{indicates text missing or illegible when filed}$$

where Pᵤ is the factored axial load combination and ρ_{w} is the longitudinal steel reinforcement ratio. For spiral columns, the approximate constant term 0.40 is replaced by 0.50 in equation (1.2).

Given the existing boundary conditions at the column ends and the initial cross-sectional dimensions, A_{g,trial} is used to calculate the slenderness ratio of said column to evaluate if buckling effects can be neglected. When these effects are negligible, the column is classified as “short” and designed assuming failure under crushing. In this scenario, the design proceeds with reinforcement detailing and analysis of the combined effects of factored axial loads (Pᵤ) and moments (Mᵤ) in determining column nominal capacity. At this stage, A_{g,trial} and ρ_{w} are adjusted using interaction (P-M) diagrams, where the point representing factored load demands, (Pᵤ, Mᵤ), can be located within the design strength, (ϕPₙ, ϕMₙ) interaction surface. When slenderness effects are not negligible, the column is defined as “long” or “slender” and the expected failure mode falls under buckling. In this case, 2^{nd}-order moments can be accounted for when determining load demands. Section 6.2.5.3 of ACI 318-19 proposes a flowchart to determine column slenderness effects. Typically, the moment magnification method is used to estimate 2^{nd}-order moments. This method consists in determining the critical buckling load P_{c} used to calculate the moment magnifier δ, which amplifies the 1^{st}-order moments to account for 2^{nd}-order effects. According to ACI 318-19, δ should be kept under 1.4 to avoid excessive moments that may otherwise be inaccurately estimated using the moment magnification method. ACI specifies that, when δ>1.4, the structural system can be revised. Once the system is revised (i.e., δ<1.4), δ is then used to calculate the factored moments that include 2^{nd} order effects.

During structural analysis, reinforcement detailing follows code specifications to ensure that columns are not only safe under axial loads and bending, but also shear and torsion. Design factors involving multi-member interactions (e.g., punching shear, drift, seismic) are a function of the structural system and often rule the final design of RC columns. Finally, spacing and constructability constraints are also be satisfied to ensure seamless operations and assemblage of the elements in situ.

The disclosed workflow allows environmental metrics to be incorporated into the structural design process of RC columns. This workflow can be implemented in hardware or a suitable combination of hardware and software, using algorithms that allow designers to estimate the environmental impacts associated with casting RC columns with different shapes, reinforcement ratios and concrete mixtures, or in other suitable manners. For each concrete mix design available and their intrinsic mechanical properties, costs and embodied CO₂, the disclosed workflow estimates the best suited column shape, dimensions and reinforcement ratio that are more likely to result in the set of columns with the lowest cost and embodied CO₂ for the entire building under analysis. It is important to note that the disclosed workflow follows design provisions from ACI 318-19 prior to (P-M) analyses and reinforcement detailing and is intended to provide recommendations on materials and trial cross-sections entering these design stages. This process may involve a few iterations when the combined effect of (P-M) requires significant changes to the area of the column or major increases in reinforcement ratio. Suitable variations of the disclosed workflow will be apparent to a person of skill in the art.

This workflow starts with the calculation of Ag,limit, the gross column area defining the threshold for which slenderness effects can be neglected. While a gross column area limit metric is disclosed, a person of skill in the art will recognize that any suitable gross area limit metric can also or alternatively be used, as discussed and described further herein (e.g. for walls, load bearing elements and other suitable structural or non-structural elements). This threshold differentiates the failure mode driving design. For columns in which A_{g}>A_{g,limit}, failure is expected to occur under crushing (short columns) whereas, for columns where A_{g}<A_{g,limit}, failure is expected to occur under buckling (slender columns). According to section 6.2.5.1 of ACI 318-19, slenderness effects can be neglected when

$$\frac{K \text{?}}{r} \leq 34 + 12 \frac{M \text{?}}{M \text{?}} and \frac{K \text{?}}{r} \leq 40$$

$$\text{?} \text{indicates text missing or illegible when filed}$$

for nonsway frames and

$$\frac{K \text{?}}{r} \leq 22$$

$$\text{?} \text{indicates text missing or illegible when filed}$$

for sway frames, where Klᵤ is the effective unsupported length and r is the radius of gyration. Given these limits, we can define a slenderness limit sldₗᵢₘᵢₜ, in which sldₗᵢₘᵢₜ=22 for sway frames and

$${sld}_{limit} {=}^{min \{ 40 ; ( 34 + 12 \frac{{M}_{1}}{{M}_{2}} ) \}}$$

for nonsway frames.

Knowing that

$$r = \sqrt{\frac{I \text{?}}{A \text{?}}} ,$$

$$\text{?} \text{indicates text missing or illegible when filed}$$

this equation can be derived to define A_{g,limit} as a function of the effective unsupported length (Klᵤ), the cross-sectional shape (rectangular or circular) and the ratio of long-to-short dimensions (β). For rectangular-shaped cross-sections,

$${A}_{g . limit} = 12 β {( \frac{K \text{?}}{{sld}_{limit}} )}^{2} . \qquad ( 1.3 )$$

$$\text{?} \text{indicates text missing or illegible when filed}$$

On the other hand, for circular shaped cross-sections,

$${A}_{g . limit} = 4 π {( \frac{K \text{?}}{{sld}_{limit}} )}^{2} . \qquad ( 1.4 )$$

$$\text{?} \text{indicates text missing or illegible when filed}$$

The next step in the workflow consists in calculating A_{g,short}, which represents the minimum area required to withstand load combinations and conditions in which failure occurs under crushing. For columns subjected to small end moments (which is common for interior columns), the cross-sectional area is governed by the maximum nominal axial load capacity ϕP_{n,max} and can satisfy Pᵤ≤ϕPₙ imposed by ACI 318-19. Thus, equation (1.1) can be derived for Pᵤ≤ϕPₙ such that

$$A \text{?} \geq \frac{P \text{?}}{0.8 ϕ ( 1 - ρ \text{?} ) [ 0.85 \text{?} + \frac{f \text{?} ρ \text{?}}{( 1 - ρ \text{?} )} ]} . \qquad ( 1.5 )$$

$$\text{?} \text{indicates text missing or illegible when filed}$$

When designing RC columns, elastic first-order analysis (using prescribed section properties) are usually performed to calculate the stability index Q. This index is used to determine if columns are placed in sway or nonsway frames. For slender columns, second-order moments can be accounted through the moment magnification method. For columns in nonsway frames, the moment magnifier δₙₛ is

$$δ \text{?} = \frac{C \text{?}}{1 - \frac{P \text{?}}{0.75 P \text{?}}} \qquad ( 1.6 )$$

$$\text{?} \text{indicates text missing or illegible when filed}$$

For hinged columns or columns with axial loads and end moments, Cₘ=0.6+0.4(Mᵢ/M₁), whereas for columns subjected to transverse loads between their ends and concentrically loaded columns, Cₘ=1.0.

For sway frames, the magnification factor δₛ

$$δ \text{?} = \frac{1}{1 - \frac{\sum {P}_{u}}{0.75 \sum P \text{?}}} , \qquad ( 1.7 )$$

$$\text{?} \text{indicates text missing or illegible when filed}$$

where ΣPᵤ is the summation of all factored vertical loads in a story and ΣP_{c} is the summation of all sway-resisting columns in a story. Design of slender columns can result in a magnification factor between 1.0≤δ≤1.4. The minimum area of a slender column required to withstand load combinations and boundary conditions in which failure occurs due to buckling is defined herein as A_{g,long}. In this step of the proposed workflow, A_{g,long} is calculated for a critical axial buckling load P_{c} that forces the moment magnifier δ to be under a defined threshold. The ACI code defines P_{c} as

$$P \text{?} = \frac{{{π}^{2} ( EI )}_{eff}}{{( K \text{?} )}^{2}} . \qquad ( 1.8 )$$

$$\text{?} \text{indicates text missing or illegible when filed}$$

According to the ACI Code 318-19, the primary concern related to calculating P_{c} is the choice of the flexural stiffness (EI)_{eff} that reasonably approximates the variations in stiffness due to creep, cracking and nonlinearity of the concrete stress-strain curve. The ACI Code 318-19 proposes three alternative equations to estimate (EI)_{eff}:

$${( EI )}_{eff} = \frac{0.4 E \text{?} I \text{?}}{1 + β \text{?}} \qquad ( 1.9 )$$

$${( EI )}_{eff} = \frac{( 0.2 E \text{?} {I}_{g} E \text{?} I \text{?} )}{1 + β \text{?}} \qquad ( 1.1 )$$

$${( EI )}_{eff} = \frac{E \text{?} I}{1 + β \text{?}} , \qquad ( 1.11 )$$

$$\text{?} \text{indicates text missing or illegible when filed}$$

where the numerators represent the short-term column stiffness, whereas the term (1+β_{dns}) is used to account for creep effects. Equations (1.10) and (1.11) are mostly used during analyses stages for improved accuracy. In design stages, equation (1.9) is often used to estimate the flexural stiffness given that, at this stage, reinforcement layout is still unknown. ACI Code 318-19 recommends approximating creep effects by reducing the flexural stiffness assuming β_{dns}=0.6. Accordingly, this example embodiment will use this assumption to simplify equation (1.9) as (EI)e_{ff}=0.25E_{c}I_{g}. Conversely, equation (EI)e_{ff}=0.7 E_{c}I_{g} can be used as a lower bound estimate for the flexural stiffness of steel-fiber-reinforced UHPC slender columns.

Knowing that

$$r = \sqrt{\frac{I \text{?}}{A \text{?}}}$$

$$\text{?} \text{indicates text missing or illegible when filed}$$

and assuming (EI)e_{ff}=0.25 E_{c}I_{g}, A_{g,long} can be derived as a function of P_{c} as

$$A \text{?} \geq ( \frac{K \text{?}}{π} ) \sqrt{\frac{12 β P \text{?}}{0.25 E \text{?}}} \qquad ( 1.12 )$$

$$\text{?} \text{indicates text missing or illegible when filed}$$

for rectangular shaped cross-sections, and as

$$A \text{?} \geq K \text{?} \sqrt{\frac{4 P \text{?}}{0.25 E \text{?}}} \qquad ( 1.13 )$$

$$\text{?} \text{indicates text missing or illegible when filed}$$

for circular shaped cross-sections. For nonsway frames, setting P_{c} as a function of δ_{dns} results in

$$P \text{?} = \frac{δ \text{?} P \text{?}}{0.75 ( δ \text{?} - 0.6 - 0.4 \frac{{M}_{1}}{{M}_{1}} )} \qquad ( 1.14 )$$

$$\text{?} \text{indicates text missing or illegible when filed}$$

Similarly, for sway frames, equation (1.6) can be rearranged as a function of Po as

$$P \text{?} = \frac{P \text{?}}{0.75 ( 1 - \frac{1}{δ \text{?}} )} . \qquad ( 1.15 )$$

$$\text{?} \text{indicates text missing or illegible when filed}$$

Depending on the structural system, equations (1.6) to (1.14) can be rearranged to calculate A_{g,long} as a function of material properties, boundary conditions and load demands. Table 1 lists the parameters determining the calculation of A_{g,long}.

TABLE 1
Summary table of equations to determine
A_{g, long} for nonsway frames

| | All other cases (incl. columns |
|---|---|
| Hinged columns | in sway frames or columns |
| or columns in | subjected to transverse loads |
| nonsway frames | between their ends and |
| with axial loads | concentrically loaded |
| and end moments: | columns (no end moment): |
| For any rectangular- | For any rectangular- |
| shaped cross section: | shaped cross section: |
| [symbol] | [symbol] |
| For circular- | For circular- |
| shaped cross sections: | shaped cross sections: |
| [symbol] | [symbol] |

[symbol]

indicates data missing or illegible when filed

In this embodiment, δ can be kept under 1.4 to ensure that the trial cross-sections proceeding to reinforcement detailing are still suitable for design using the moment magnification method while minimizing cross-sectional area usage. Iterations on the A_{g,trial} during P-M analysis may require this area to be increased to satisfy moment demands, which will further lower the value of δ and therefore still satisfy code limits.

The ACI Code 318-19 does not impose minimum column dimensions. Yet, the smallest size of a cast-in-place column is typically over 20 cm (8 inches), which itself is very unlikely to be utilized. This is due to cumulative effect from other design limitations such as minimum concrete cover, which is imposed by local fire codes and class of exposure expected for the structure, and minimum spacing between longitudinal bars imposed by ACI Code 318-19. In this example embodiment, the minimum width accepted for any column side (or diameter, for circular columns) is set at 25 cm (10 inches). That is, for each cross-sectional shape and #under consideration, 25 cm is the length of the smallest side and is used to calculate the minimum practical area for constructability purposes, A_{g,min}.

When using the disclosed workflows at final stages of design (e.g., to refine material selection), new A_{g,min} can be determined for different strength classes based on reinforcement detailing requirements, as well as multi-member interactions associated with the selected structural system (e.g., punching shear, drift, etc.).

When selecting a trial area, it is important to first verify if A_{g,short} and A_{g,long} are larger than A_{g,min}. Next, these areas are compared to A_{g,limit} in order to determine the type of column that is being designed. For the given boundary conditions and concrete mixtures where A_{g,short}>A_{g, limit}, equation (1.5) can be used to define A_{g, trial} and calculate the associated costs and embodied CO₂ for the short column. If, instead, A_{g,short}<A_{g, limit}, slenderness effects cannot be neglected and Table 1 can be used to compute A_{g, trial} and calculate the associated costs and embodied CO₂ for the long/slender column.

In the workflow, the A_{g,limit} computed for each concrete mix design is used to calculate the material cost and environmental impact associated with building the designed RC columns. To this extent, the contributions from concrete, longitudinal rebars and shear reinforcement can be isolated to evaluate their individual effects. Information on the volumetric embodied CO₂ of concrete and steel are defined herein as i_{c} and iₛ, respectively. This information can be obtained from material EPDs. The designed volume of each component in the RC column is then multiplied by their volumetric cost and embodied CO₂ to compute total impacts for each column. For each A_{g,limit} computed prior to this step, the effective area of concrete is

$$A \text{?} = ( 1 - {ρ}_{w} ) A \text{?} . \qquad ( 1.16 )$$

$$\text{?} \text{indicates text missing or illegible when filed}$$

Table 2 summarizes the equations used to calculate the total environmental impact of RC columns. In regard to reference 1 of Table 2, longitudinal steel reinforcement is already deducted from the effective volume of concrete when calculating the effective cross-sectional area of concrete A_{c}. On the other hand, shear reinforcement is not included in calculations performed in cross sections due to their discrete nature (individual ties spaced along a column). Thus, the volume occupied by shear reinforcement, vol_{v,reinf}, can be further deducted from vol_{c}. For the example embodiment evaluated here, impacts associated with shear reinforcement were minimal (see results section) compared to the contributions from concrete mix and longitudinal rebars. Therefore, derivations associated with shear reinforcement may need to be accommodated. Total material cost is defined herein as $ₜₒₜₐₗ and computed using the same equations presented in Table 2 to calculate total environmental impacts (Ĩₜₒₜₐₗ) In this case, the volumetric environmental metrics for concrete and steel (i_{c} and iₛ) are replaced with volumetric unit costs (u_{c} and uₛ, respectively).

FIG. 2 is a diagram of an algorithm 200 for incorporating cost and environmental parameters into a structural design and/or manufacture process, in accordance with an example embodiment of the present disclosure. Algorithm 200 can be implemented in hardware or a suitable combination of hardware and software and can utilize system 100 or one or more components or subcomponents of system 100.

Algorithm 200 begins at 202, where the AG,limit and AG,min is calculated for the given boundary conditions, as discussed and described in greater detail herein, such as in the discussion of FIGS. 3-9. While a gross column area minimum metric is disclosed, a person of skill in the art will recognize that any suitable gross area minimum metric can also or alternatively be used, as discussed and described further herein (e.g. for walls, load bearing elements and other suitable structural or non-structural elements). The algorithm then proceeds to 204.

At 204, the AG,short and AG,long are calculated for each concrete mix evaluated, as discussed and described in greater detail herein, such as in Table 1 below and the discussion of FIGS. 3-9. While gross column area short and long metrics are disclosed, a person of skill in the art will recognize that any suitable gross area short metric and gross area long metric can also or alternatively be used, as discussed and described further herein (e.g. for walls, load bearing elements and other suitable structural or non-structural elements). The algorithm then proceeds to 206.

At 206, it is determined whether AG,short is greater than AG,min, as discussed and described in greater detail herein, such as in the discussion of FIGS. 3-9. If so, the algorithm proceeds to 210, otherwise the algorithm proceeds to 208 and AG,min is set to AG,short, as discussed and described in greater detail herein, such as in the discussion of FIGS. 3-9. The algorithm then proceeds to 210.

At 210, it is determined whether AG,short is greater than AG,limit, as discussed and described in greater detail herein, such as in the discussion of FIGS. 3-9. If so, the algorithm proceeds to 212 where AG,short is set to AG,trial, as discussed and described in greater detail herein, such as in the discussion of FIGS. 3-9, and the algorithm then proceeds to 214. While a a area trial metric is disclosed, a person of skill in the art will recognize that any suitable gross area trial metric can also or alternatively be used, as discussed and described further herein (e.g. for walls, load bearing elements and other suitable structural or non-structural elements). Otherwise, the algorithm proceeds directly to 214.

At 214, it is determined whether AG,long is greater than AG,min, as discussed and described in greater detail herein, such as in the discussion of FIGS. 3-9. If so, the algorithm proceeds 218, otherwise the algorithm proceeds to 216 where AG,min is set to AG,long, as discussed and described in greater detail herein, such as in the discussion of FIGS. 3-9, and then the algorithm proceeds to 218.

At 218, AG,long is set to AG,trial, as discussed and described in greater detail herein, such as in the discussion of FIGS. 3-9. The algorithm then proceeds to 220.

At 220, I and C are calculated for each concrete mix available using Table 2 as shown below, and as discussed and described in greater detail herein, such as in the discussion of FIGS. 3-9. The algorithm then proceeds to 222.

TABLE 2
Equations used to calculate the total environmental
impact of RC columns

* Ĩₜₒₜₐₗ = Ĩ_{c} + I [symbol] + I [symbol]
Ĩₜₒₜₐₗ -> total embodied CO₂ of a steel reinforced concrete column
Ĩ_{c} -> contribution of concrete to embodied CO₂ of the column
Ĩ [symbol] -> contribution of longitudinal reinforcement to embodied CO₂ of the column
Ĩ [symbol] -> contribution of shear reinforcement to embodied CO₂ of the column
* Ĩ_{c} = vol_{c} × i_{c} ⇔ Ĩ_{c} = (A_{c}L − vol_{v,reinf} ) × i_{c}
vol_{c} -> effective volume of concrete
i_{c} -> concrete GWP declared in EPDs (in units of mass of equivalent CO₂ per unit volume)
A_{c} -> effective area of concrete
L -> length of the column
vol_{v,reinf} -> volume of shear reinforcement [symbol]
${\tilde{I}}_{sw} = {vol}_{sw} \times {i}_{s} ⇔ {\tilde{I}}_{sw} = {A}_{st} \times L \times {i}_{s} ⇔ {\tilde{I}}_{sw} = {ρ}_{w} {A}_{g} \times L \times {i}_{s} ⇔ {\tilde{I}}_{sw} = \frac{{i}_{1} {ρ}_{w} {A}_{c} L}{( 1 - {ρ}_{w} )}$
vol [symbol] -> volume of longitudinal steel reinforcement
iₛ -> steel GWP declared in EPDs (in units of mass of equivalent CO₂ per unit volume)
A [symbol] -> total area of nonprestressed longitudinal reinforcement including bars or steel shapes
${\tilde{I}}_{sw} = {vol}_{V . reinf} \times {i}_{s} ⇔ {\tilde{I}}_{sw} = {I}_{s} \times \frac{{A}_{w}}{s} \times L \times {i}_{s} ( tied columns ) or {\tilde{I}}_{sp} = {I}_{sp} \times {A}_{sp} \times \frac{L}{s} \times {i}_{s}$
I [symbol] -> total tie length within spacing s (in)
Iₛₚ -> length of one turn of the spiral (in)
A [symbol] -> area of nonprestressed reinforcement in a tie
Aₛₚ -> area of the spiral bar (in²);
s -> center-to-center spacing between transverse reinforcement (or spiral pitch) [symbol]
indicates data missing or illegible when filed

At 222, the best suited concrete mix and associated column shape and reinforcement ratio are selected, such as using system 100 and as discussed and described in greater detail herein, such as in the discussion of FIGS. 3-9. The algorithm then proceeds to 224.

At 224, it is determined whether AG,trial equals AG,short, as discussed and described in greater detail herein, such as in the discussion of FIGS. 3-9. If so, the algorithm proceeds 226 where a P-M analysis is performed considering only the first order moments, as discussed and described in greater detail herein, such as in the discussion of FIGS. 3-9. Otherwise, the algorithm proceeds at 228 where second order moments are calculated and used to perform the P-M analysis, as discussed and described in greater detail herein, such as in the discussion of FIGS. 3-9.

In operation, algorithm 200 is used to incorporate cost and environmental parameters into a structural design and/or manufacturing process, as discussed and described in greater detail herein, such as in the discussion of FIGS. 3-9. While algorithm 200 is shown as a flow chart, a person of skill in the art will recognize that it can also or alternatively be implemented using object-oriented programming, a state diagram, a ladder diagram or in other suitable manners.

Environmental impact factors and unit costs can be used to compute the volumetric GWP and costs associated with different concrete formulations. Raw material costs can be obtained from suitable sources, and GWP factors can be derived from a cradle-to-gate life cycle assessment (LCA) approach that quantifies direct and supply-chain GWP from materials used in concrete production. For the PLC used in two concrete mixtures evaluated in this work, the GWP factor was estimated from an available environmental product declaration (EPD). It is important to note that, when EPDs are not made available by concrete suppliers, GWP factors from concrete production can be estimated using a variety of LCA tools available. For more precise estimations of cost and environmental impacts throughout a structure's service life, a cradle-to-grave boundary system or other suitable processes can also or alternatively be used.

Regarding steel reinforcement, two main manufacturing routes are typically adopted to process pig iron and refine it into crude steel: basic oxygen furnaces (BOF) and electric arc furnaces (EAF). Steel rebars produced with EAF currently have a carbon footprint 3 to 4 times lower than BOF rebars, depending on the amount of recycled steel scrap used. While BOF currently allows the use of up to 30% of steel scrap, EAF can have contents up to 100%. According to the Steel Manufacturers Association, over 70% of all steel in the United States is currently produced using EAF. On the other hand, a recent report from the International Energy Agency indicates that 70% of global crude steel production still runs through the BOF route.

The present disclosure provides an example analysis with GWP factors for rebars produced using both routes, BOF and EAF, to evaluate their contribution to the total embodied CO₂ of RC columns. Two extreme scenarios are considered: 1) EAF rebars with >98% steel scrap and 2) BOF rebars with no steel scrap. The GWP factor for rebars produced in BOF with no addition of steel scrap can be estimated from a suitable source. For steel rebars produced in EAFs, where steel scrap contents over 98% are typically used, GWP can be estimated by averaging the values reported in EPDs by various steel rebar suppliers. Grade 60 can be assigned for all reinforcing bars, with an estimated unit cost of $550 US dollars (USD) per ton. Finally, GWP from steel fibers can be estimated from a suitable source. Table 3 summarizes the unit costs and GWP factors used in this example embodiment.

TABLE 3
Estimated GWP and unit cost factors (of raw
materials) defined on a per-mass basis

| | *GWP | unit |
|---|---|---|
| | factor | cost |
| | (kg CO₂- | (USD/ |
| Material | eq/kg) | ton) |
| Slag | 0.022 | $70 |
| Microsilica | 0.022 | $600 |
| Fly Ash | 0.022 | $25 |
| Ordinary portland cement | 1.145 | $90 |
| Portland limestone cement | 0.856 | $90 |
| Water | 0.005 | $0.80 |
| HRWR | 0.794 | $3,000 |
| Natural sand | 0.038 | $10 |
| Coarse aggregate | 0.036 | $40 |
| Crushed sand | 0.039 | $40 |
| Ground quartz | 0.041 | $220 |
| Steel fibers | 0.880 | $3,940 |
| EAF steel reinforcement (>98% | 0.770 | $550 |
| steel scrap) | | |
| BOF Steel reinforcement (no steel | 2.270 | $550 |
| scrap) | | |

A dataset with 30 concrete formulations was compiled to perform the analysis in this example, but other suitable sources can also or alternatively be used. In this dataset, 10 different concrete mixtures were considered for each of the 3 types of concrete technologies evaluated: NSC, HPC and UHPC. Given the recent wide adoption of PLC across various states in the USA, two of the evaluated NSC mixtures contain 15% clinker replacement with limestone powder. Table 4 contains information on the source, mix proportions, binder content, 28-day compressive strength, volumetric GWP and unit cost for every concrete mixture considered for this example embodiment.

TABLE 4
Concrete formulations considered for analysis

| | | | | | | | aggregates (% by wt.) replacing | | | | | | | | |
|---|---|---|---|---|---|---|---|---|---|---|---|---|---|---|---|
| | | SCMs (% by wt.) | | | | | cementitious content | | | | | binder | GWP | **unit | 28^{th}- |
| *Mix | | replacing cement | | | w/ | HRWR/ | Sand | Sand | | | | (% by | (kg COreq/ | cost | day [symbol] |
| Design | Ref. | SL | SF | FA | cm | cm | 1 | 2 | LS | GQ | CA | vol) | m [symbol] ) | (U [symbol] /m [symbol] ) | (MPa) |
| UHPC-1 | [101] | 22 | 5.3 | 2.0 | 0.20 | 1.38% | 0.0 | 5.5 | 0.0 | 22.0 | 0.0 | 77.2 | 1281.5 | 774.2 | 158.1 |
| UHPC-2 | [101] | 22 | 5.3 | 2.0 | 0.20 | 1.38% | 22.0 | 8.5 | 0.0 | 21.5 | 0.0 | 56.2 | 979.2 | 780.0 | 154.8 |
| UHPC-3 | [102] | 0 | 15.8 | 0 | 0.13 | 2.33% | 46.8 | 0.0 | 0.0 | 2.7 | 0.0 | 54.8 | 1264.5 | 852.7 | 121.0 |
| UHPC-4 | [103] | 0 | 16.7 | 16.3 | 0.14 | 2.63% | 0.0 | 0.0 | 0.0 | 50.1 | 0.0 | 56.6 | 1019.1 | 1055.4 | 199.9 |
| UHPC-5 | [104] | 0 | 20.0 | 0 | 0.22 | 1.12% | 9.7 | 38.2 | 0.0 | 8.7 | 0.0 | 53.9 | 994.8 | 811.2 | 192.0 |
| UHPC-6 | [104] | 0 | 20.0 | 0 | 0.22 | 1.12% | 9.3 | 36.9 | 0.0 | 9.0 | 0.0 | 55.2 | 1016.1 | 813.4 | 201.0 |
| UHPC-7 | [104] | 0 | 20.0 | 0 | 0.22 | 1.50% | 15.5 | 36.5 | 0.0 | 9.3 | 0.0 | 49.2 | 921.8 | 814.1 | 175.8 |
| UHPC-8 | [104] | 0 | 20.0 | 0 | 0.22 | 1.60% | 0.0 | 52.0 | 0.0 | 9.3 | 0.0 | 49.7 | 924.4 | 805.0 | 171.0 |
| UHPC-9 | [104] | 0 | 20.0 | 0 | 0.22 | 1.60% | 9.7 | 38.2 | 0.0 | 8.7 | 0.0 | 54.6 | 996.9 | 821.1 | 190.0 |
| UHPC-10 | [104] | 0 | 20.0 | 0 | 0.18 | 1.92% | 9.4 | 38.1 | 0.0 | 8.7 | 0.0 | 52.6 | 1040.5 | 859.6 | 163.0 |
| HPC-1 | [101] | 22 | 5.3 | 2.0 | 0.20 | 1.38% | 20.5 | 25.0 | 0.0 | 25.0 | 0.0 | 37.8 | 620.5 | 257.7 | 35.0 |
| HPC-2 | [101] | 22 | 5.3 | 2.0 | 0.20 | 1.38% | 15.0 | 15.0 | 0.0 | 12.5 | 0.0 | 65.2 | 1020.7 | 255.8 | 74.8 |
| HPC-3 | [101] | 22 | 5.25 | 2.0 | 0.20 | 1.33% | 20.0 | 25.0 | 0.0 | 21.5 | 0.0 | 42.1 | 682.4 | 250.2 | 105.0 |
| HPC-4 | [105] | 0 | 0 | 44.9 | 0.23 | 3.84% | 29.2 | 0.0 | 0.0 | 0.0 | 42.0 | 40.6 | 478.9 | 154.1 | 77.6 |
| HPC-5 | [105] | 0 | 0 | 0 | 0.19 | 3.10% | 28.0 | 0.0 | 0.0 | 0.0 | 41.4 | 39.0 | 894.5 | 216.5 | 84.1 |
| HPC-6 | [106] | 0 | 5.0 | 0 | 0.40 | 0.00% | 30.6 | 0.0 | 0.0 | 0.0 | 51.5 | 30.1 | 491.9 | 97.7 | 60.3 |
| HPC-7 | [106] | 0 | 5.0 | 0 | 0.50 | 0.00% | 28.2 | 0.0 | 0.0 | 0.0 | 52.7 | 34.5 | 496.0 | 96.5 | 49.8 |
| HPC-8 | [107] | 0 | 10.1 | 0 | 0.31 | 2.51% | 37.1 | 0.0 | 0.0 | 0.0 | 42.8 | 31.0 | 536.7 | 143.8 | 62.9 |
| HPC-9 | [107] | 0 | 9.9 | 0 | 0.30 | 2.49% | 35.2 | 0.0 | 0.0 | 0.0 | 42.9 | 32.8 | 575.6 | 150.7 | 82.3 |
| HPC-10 | [102] | 0 | 16.7 | 0 | 0.13 | 2.52% | 48.2 | 0.0 | 0.0 | 2.7 | 0.0 | 53.9 | 1127.6 | 303.0 | 70.0 |
| NSC-1 | [108] | 0 | 0 | 0 | 0.41 | 0.56% | 27.5 | 0.0 | 0.0 | 0.0 | 54.7 | 30.3 | 514.7 | 96.3 | 34.8 |
| NSC-2 | [108] | 0 | 0 | 40 | 0.40 | 0.64% | 27.4 | 0.0 | 0.0 | 0.0 | 54.7 | 31.8 | 333.3 | 85.2 | 35.0 |
| NSC-3 | [108] | 0 | 0 | 45 | 0.41 | 0.66% | 27.5 | 0.0 | 0.0 | 0.0 | 54.7 | 32.2 | 309.2 | 83.7 | 23.1 |
| NSC-4 | [108] | 0 | 0 | 50 | 0.40 | 0.69% | 27.5 | 0.0 | 0.0 | 0.0 | 54.7 | 32.1 | 288.2 | 82.8 | 21.6 |
| NSC-5 | [106] | 0 | 0 | 15 | 0.50 | 0.00% | 27.6 | 0.0 | 0.0 | 0.0 | 53.1 | 35.2 | 450.3 | 82.2 | 42.5 |
| NSC-6 | [106] | 0 | 0 | 45 | 0.50 | 0.00% | 26.3 | 0.0 | 0.0 | 0.0 | 54.1 | 36.9 | 313.7 | 73.8 | 30.9 |
| NSC-7 | [106] | 0 | 0 | 55 | 0.50 | 0.00% | 25.9 | 0.0 | 0.0 | 0.0 | 54.4 | 37.4 | 268.3 | 71.0 | 20.8 |
| NSC-8 | [106] | 0 | 0 | 40 | 0.50 | 0.00% | 26.4 | 0.0 | 0.0 | 0.0 | 54.3 | 36.8 | 313.6 | 85.2 | 33.6 |
| PLC-1 | [109] | 0 | 0 | 0 | 0.35 | 1.43% | 28.1 | 0.0 | 15.0 | 0.0 | 59.9 | 22.4 | 289.7 | 81.4 | 36.1 |
| PLC-2 | [109] | 0 | 0 | 0 | 0.35 | 1.43% | 28.1 | 0.0 | 15.0 | 0.0 | 59.9 | 22.4 | 289.8 | 81.4 | 36.6 |

Ref—reference;
SCM—supplementary cementitious materials;
HRWR—high range water reducer;
cm—cementitious materials;
w—water;
SL—slag;
SF—silica fume;
FA—fly ash;
LS—limestone powder;
GQ—ground quarts;
CA—coarse aggregate
*All UHPC formulations have a 2% volume fraction of discontinious steel fiber reinforcement
**raw material costs are referred to in this work as unit costs. However, these costs do not include batching, transportation, service and profit. [symbol]
indicates data missing or illegible when filed

Unit costs listed in Table 4 correspond to the cumulative costs of the raw materials used in each mix design rather than the actual market price of a given concrete mix. This is due to the fact that the concrete mixtures listed in Table 4 are formulations collected from the literature. Considering the large spectrum of costs associated with batching, transportation, service and profit for different regions, producers and concrete technologies, these costs are assumed constant for all concrete alternatives evaluated herein and not included in the analysis. Also, the baseline cost of construction materials has increased substantially in recent years. Therefore, each design alternative obtained in this example will be compared in terms of percent change in cost, which ought to remain fairly constant.

FIG. 3 is a diagram 300 of a 12-story RC office building, in accordance with an example embodiment of the present disclosure. The 12-story RC building is presented as an example embodiment to demonstrate the disclosed workflow. The analysis includes identifying the most suitable materials (concrete mix design, rebar type and content) and column configuration (size and shape) to minimize the total embodied CO₂ associated with RC columns. The workflow does not require changes to the structural analysis process and allows the user to initiate the design process with a trial cross-section and concrete mix that are supported by cost and environmental considerations rather than counting on prior experience.

The height of the first story 302 is 4.06 m (13 ft, 4 in), while the other floors 304 stand at 3.15 m (10 ft, 4 in). Lateral load effects on the building are assumed to be caused by wind, while dead loads are assumed to be the only sustained loads. Given the symmetry of the frame, gravity loads are not expected to cause appreciable sidesway. It is important to note that the iterations performed in the disclosed process do not involve changes in beam and slab dimensions. Hence, given the small contribution from the columns to the sustained dead loads in this building (˜0%), the assumption is made that all columns are placed in sway frames. To simplify the optimization task, columns in this building are assigned to 4 categories as shown in Table 5.

TABLE 5
Column group partition considered during design

| | | Column location in plant | |
|---|---|---|---|
| | | Interior columns | Exterior columns |
| Column location | Floors 1 to 2 | [symbol] | E₁₋₂ |
| by floor | Floors 3 to 12 | [symbol] | E₃₋₁₂ |

[symbol]

indicates data missing or illegible when filed

Load combinations (Pᵤ) are calculated for each column group partition (i.e., column design group). Table 6 lists the variables considered for the optimization task. The domain of all possible combinations results in 1920 alternative designs for each of the 4 column design groups listed in Table 6.

TABLE 6
Optimization variables
Variables

| | Concrete formulations | [symbol] | Column Type | Rebar type |
|---|---|---|---|---|
| Levels | 30 mix designs | 1% | Circular column with ties | EAF |
| | (Table 4) | | Circular column with spirals | |
| | | 2% | β = 1.0 squared column with ties | |
| | | | β = 1.2 rectangular column with ties | |
| | | 3% | β = 1.4 rectangular column with ties | BOF |
| | | | β = 1.6 rectangular column with ties | |
| | | 4% | β = 1.8 rectangular column with ties | |
| | | | β = 2.0 rectangular column with ties | |

* β = ratio of long-to-short dimensions in rectangular columns [symbol]
indicates data missing or illegible when filed

The effects of changing column shape, rebar type and reinforcement ratio on the total embodied CO₂ of RC columns were evaluated first for the proposed building. To isolate these variables, the concrete mixture was kept constant while varying the other optimization variables.

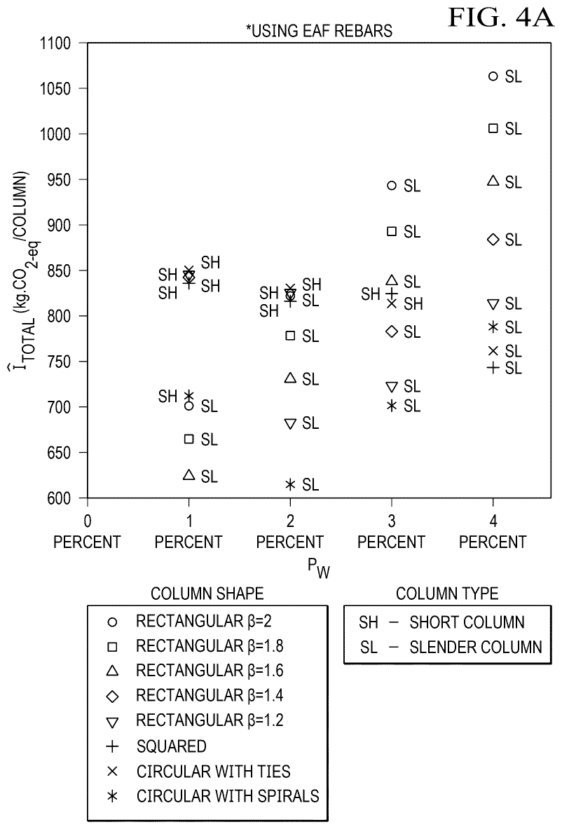

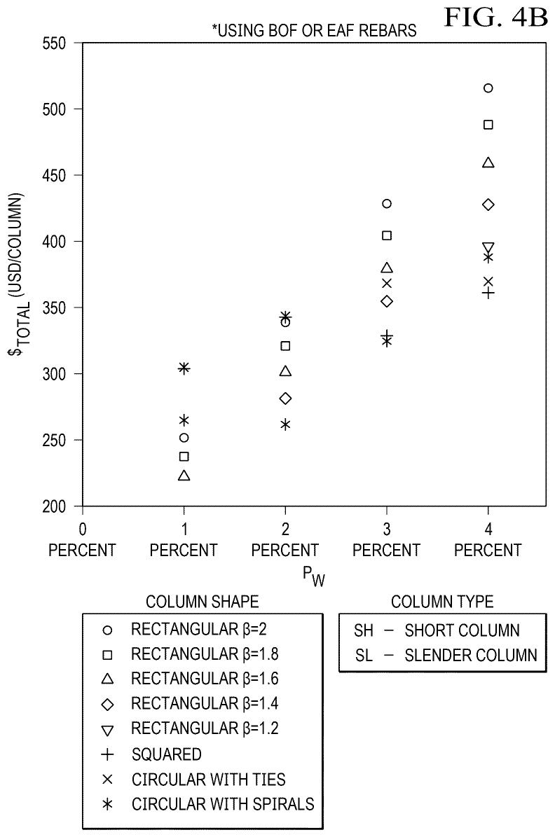

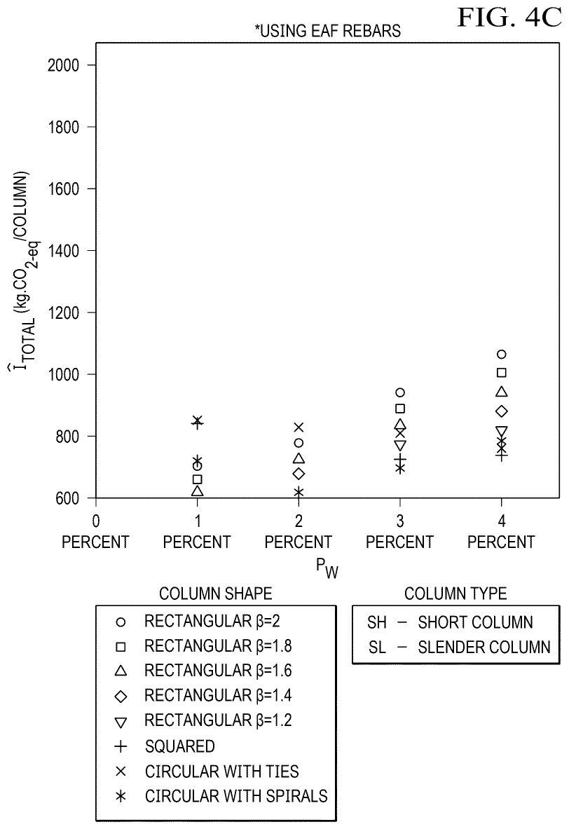

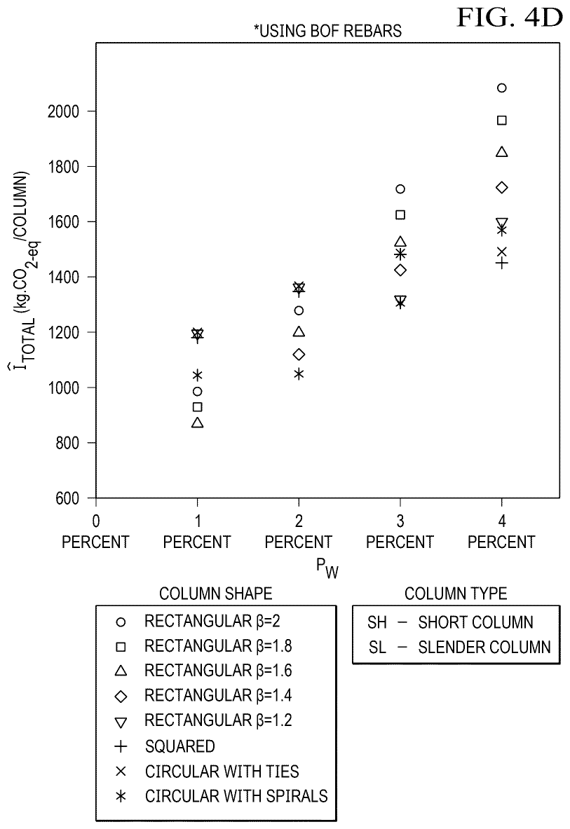

FIGS. 4A-4D are diagrams of graphs of the results for interior columns placed on the first floor when cast with mix NSC-7. The design alternatives were subjected to the same loading conditions. Several trends that contradict existing misconceptions related to the use of steel rebars in RC columns can be observed in FIGS. 4A through 4D. Optimization strategies have been focused on minimizing CO₂ emissions from steel rebar production as well as their usage in RC members. However, FIGS. 4A through 4D show that decreasing p, alone does not guarantee designing the column with the lowest embodied CO₂. For instance, FIG. 4A shows that casting a squared. concrete column with EAF rebars at ρ_{ω}=4% produces 12.5% less CO₂ than casting a squared column with ρ_{ω}=1%.

In this case, the rebar contribution to column capacity allowed the column with higher steel content to be designed as slender as opposed to the column with less steel content, which required a short column design. This allowed a 42% volume reduction for the slender column with ρ_{ω}=4% (Ag=60×60 cm²) compared to the short column with ρ_{ω}=1% (Ag=79×79 cm²). For this particular mix (NSC-7) and column design group (I1-2), the design that produces the least embodied CO₂ consists of a slender circular column with ρ_{ω}=2% and spiral reinforcement.

FIGS. 4A through 4D also show the importance of concurrent optimization efforts between column shape and ρ_{ω}, even in cases where a single concrete mixture is available. From FIG. 4A, it is evident that choosing a rectangular column with β=2 and ρ_{ω}=4% produces 43% more CO₂ than a squared column with the same ρ_{ω}, and nearly double the amount of CO₂ compared to a spiral circular column with ρ_{ω}=2%. In contrast, FIG. 4B shows a higher correlation between ρ_{ω} and costs compared to embodied CO₂. Yet, reducing p, alone also does not guarantee the column with the lowest cost. For instance, a circular spiral column with ρ_{ω}=3% has a similar cost compared to square and circular tied columns with ρ_{ω}=1%. Graphs 400 also show that no particular shape consistently produced the column with the lowest cost or embodied CO₂. In fact, different shapes were observed to be the optimum solution at different p levels.

FIGS. 4C and 4D show the embodied CO₂ associated with using EAF and BOF rebars, respectively. Columns designed with EAF rebars had associated carbon footprints between [600-1100] kg.CO₂-eq/column, while columns with BOF rebars produced between [850-2000] kg.CO₂-eq/column. As expected, results suggest that EAF rebars tend to produce the columns with the lowest CO₂ compared to BOF rebars. However, lowering the embodied CO₂ of the rebars alone does not guarantee the RC column with the lowest CO₂. This is the case for tied rectangular columns with β=1.6 and BOF rebars at ρ_{ω}=1%, which have a similar carbon footprint compared to a squared column with EAF rebars at ρ_{ω}=1%. Contributions from concrete and steel reinforcement to column carbon footprint. Design solutions using concrete mix NSC-7 were further evaluated to determine the individual contributions from concrete and steel to the total embodied CO₂ of RC columns.

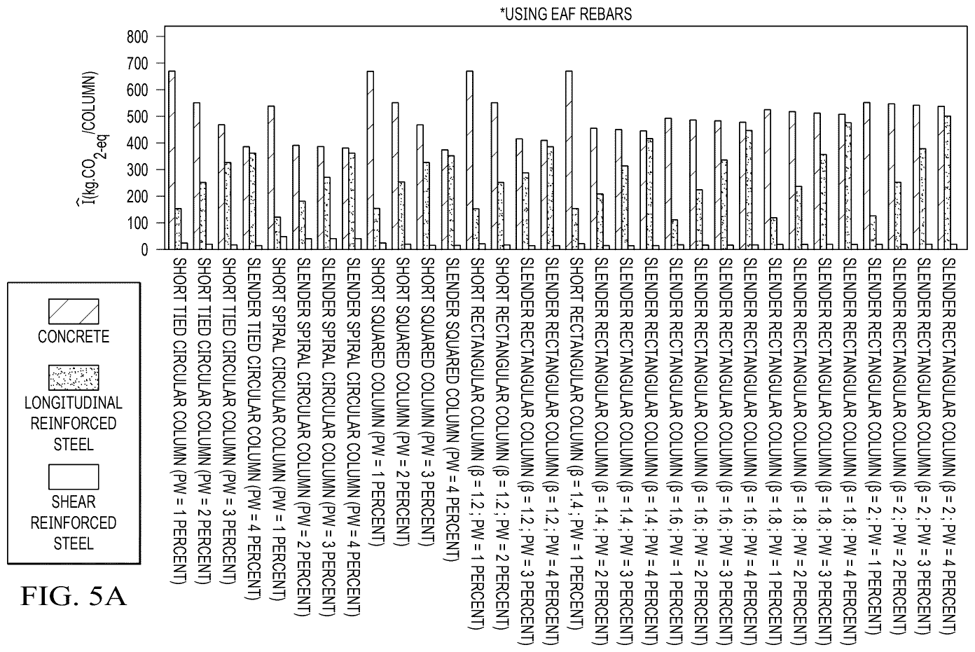

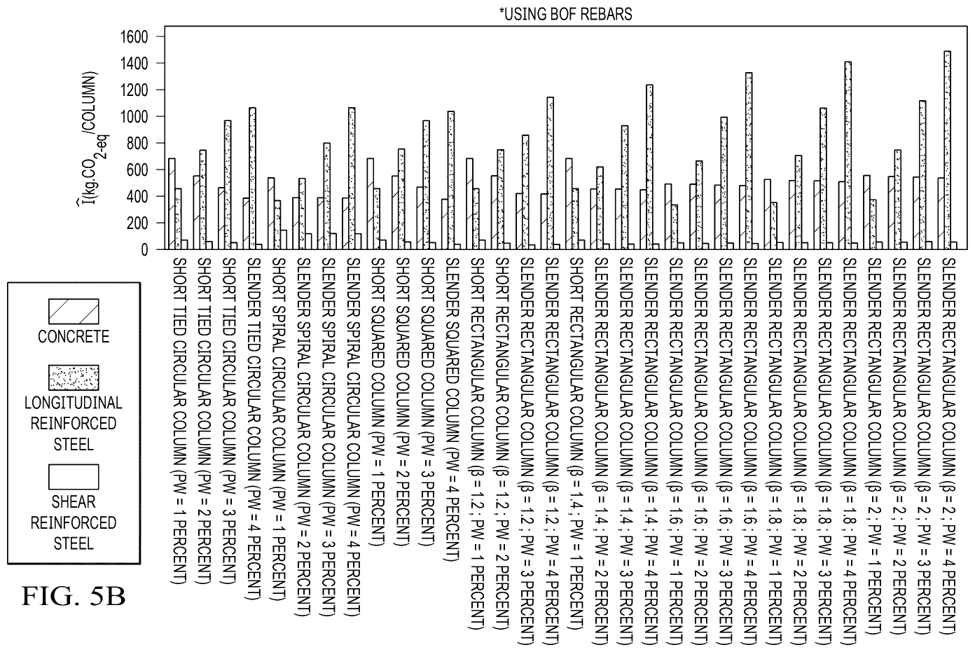

FIGS. 5A and 5B are charts showing the contributions from concrete mix, longitudinal steel reinforcement and shear reinforcement to the total embodied CO₂ of interior columns placed on the first floor of the RC building. These results show that, even though steel is used at a much lower volume fraction compared to concrete (ρ_{ω}<4%), the contribution from steel rebars to the embodied CO₂ of RC columns can, at times, surpass the contribution from concrete. In fact, when using BOF rebars (which are produced in a less ecological manufacturing route), the ratio of steel-to-concrete related CO₂ emissions reached a factor of 3 for certain design solutions. For instance, for rectangular columns with β=1.6 and BOF rebars at p, =4%, the concrete fraction is responsible for 480 kg.CO₂-eq whereas longitudinal rebars contribute with nearly 1400 kg.CO₂-eq. This is due to the fact that steel has a density of 7,821 kg/m³ and a GWP of 2.27 kg.CO₂-eq/kg (for BOF rebars), which leads to a much higher volumetric GWP (17,754 kg.CO₂-eq/m³) compared to the concrete mix NSC-7 (268 kg.CO₂-eq/m³). This trend was also observed for EAF rebars even though these bars contain a much lower GWP (0.7 kg.CO₂-eq/kg). In particular, for slender circular columns cast with EAF rebars at p, =4% and spiral reinforcement, the concrete's contribution amounts to 385 kg.CO₂-eq while longitudinal and shear reinforcement combine for up to 403 kg.CO₂-eq. Ultimately, for this particular concrete mix and rebars, the carbon footprint associated with using one unit volume of steel surpasses the contribution from concrete by a factor of 66 for BOF rebars and a factor of 20 for EAF rebars.

EPDs have been prominently used in the construction industry to quantify and, at times, incorrectly compare the carbon footprint associated with using different concrete solutions. To quantify the error associated with comparing final RC products on a per-unit-volume-of-material basis, this section discusses the correlation between volumetric indicators and total impacts (costs and embodied CO₂) from casting all 288 columns presented in the 12-story building layout from FIG. 3. First, the correlations between total embodied CO₂ versus binder content and compressive strength are evaluated.

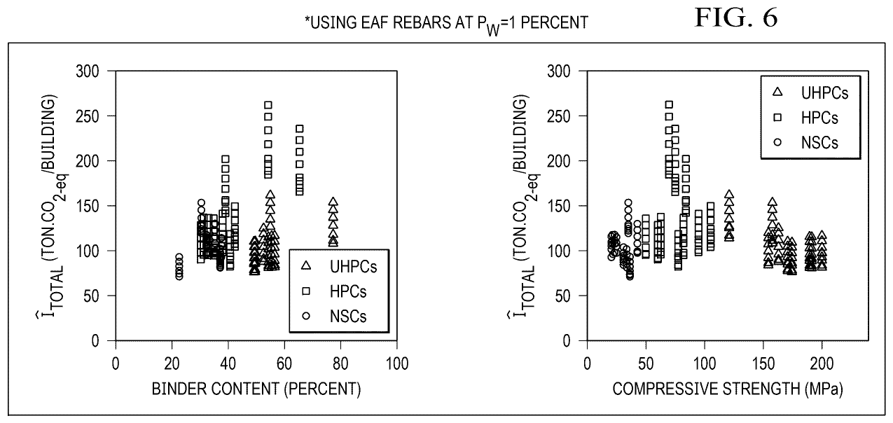

FIG. 6 is a diagram 600 showing the results for the example embodiments listed in Table 4, as well as all column types listed in Table 6. For this discussion, only EAF rebars at ρ_{ω}=1% are considered given that similar trends were observed from all ρ_{ω}.

UHPC and HPC materials typically have higher binder contents and compressive strengths compared to NSC. Diagram 600 shows that decreasing the binder content of the concrete mixture does not necessarily decrease the total carbon footprint of the designed building. In fact, there is no clear correlation between binder content and total carbon footprint produced by the columns. Similarly, the results show that concretes with increased compressive strengths do not lead to designing buildings with increased carbon footprints. Overall, diagram 600 shows that eco-efficiency is independent of concrete type given that good and bad solutions were obtained with all concrete technologies.

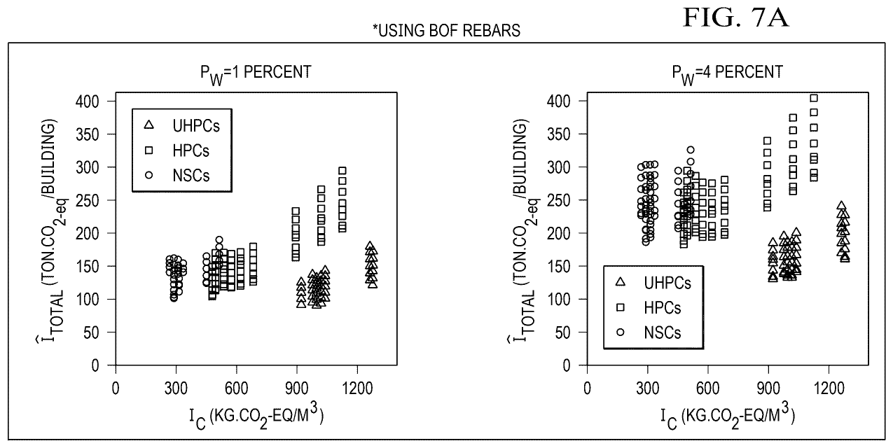

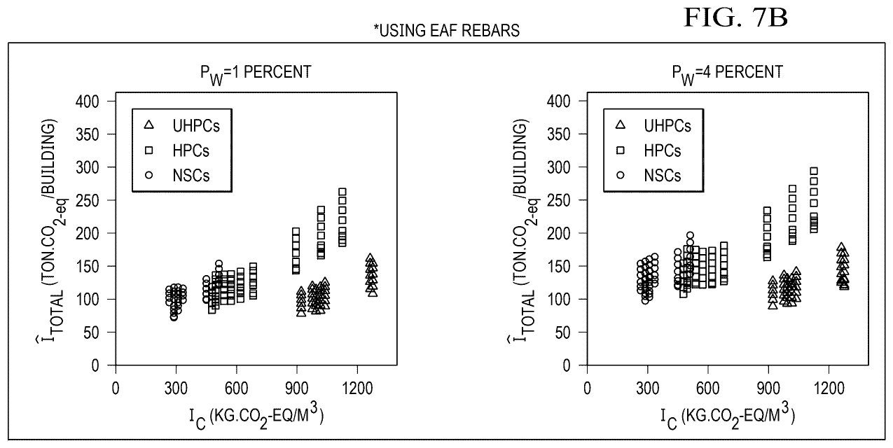

FIGS. 7A and 7B are diagrams showing correlations between the material's volumetric embodied CO₂ versus the total CO₂ produced to cast all columns, in accordance with an example embodiment of the present disclosure. RC columns cast with EAF and BOF rebars are compared at two different reinforcement levels: ρ_{ω}=1% and ρ_{ω}=4%. Diagram 700 shows that using concretes with low embodied CO₂ on a per-unit-volume basis (i_{c}) does not result in columns with the lowest overall embodied CO₂. In fact, for low reinforcement ratios (ρ_{ω}=1%), optimum solutions can be obtained with all three concrete technologies (NSC, HPC and UHPC), provided that the ideal column shape and type is selected for design. As the reinforcement ratio is increased to 4%, the most eco-efficient solutions appear to be associated with UHPC formulations. This outcome might seem unexpected due to the limited application of UHPC in RC columns. To date, only a few studies have evaluated slender UHPC columns. Even then, testing loads are usually selected to replicate loads in mid-rise and high-rise buildings. These results motivate further evaluation of UHPC columns for seismic regions, where high ρ_{ω}, are required for ductility.

FIGS. 7A and 7B also show that sustainability efforts focused solely on minimizing steel content and embodied CO₂ at the material level are inefficient to reduce the total carbon footprint of RC buildings. As evidence, consider initiating the design with rectangular columns, β=2, EAF rebars (iₛ=5 475 kg.CO₂-eq/m³), ρ_{ω}=1% and mix NSC-2 (i_{c}=333 kg.CO₂-eq/m³) as option #1.This option is marginally better compared to another solution (option #2) with squared columns, BOF rebars (is =17,754 kg.CO₂-eq/m³), ρ_{ω}=4% and mix UHPC-4 (i_{c}=1019 kg.CO₂-eq/m³). Although option #2 involves materials with 3 times higher CO₂ intensities (300% increase) and a steel content 4 times higher, the flexural stiffness obtained with mix UHPC-4 allowed the columns to be designed with considerably less volume of material compared to option #1, resulting only in a 16% increase in CO₂ to cast all columns in the building. Table 7 describes these two solutions.

TABLE 7
Option 1: rectangular shape, β = 2, NSC-2, [symbol] =
1%, EAF bars vs Option 2: squared shape, UHPC-4, [symbol] = 4%, BOF bars

| Mix | Column group | Interior columns | Exterior columns | [symbol] |
|---|---|---|---|---|
| [symbol] | [symbol] | [symbol] | [symbol] | 115 |
| | [symbol] | [symbol] | [symbol] | |
| [symbol] | [symbol] | [symbol] | [symbol] | 134 |
| | [symbol] | [symbol] | [symbol] | |

[symbol]

indicates data missing or illegible when filed

Given that 70% of global crude steel production still runs through the BOF route (including 30% of total steel production in the USA), it is imperative that design strategies include synergistic optimization approaches to capture the contribution from all the variables in the system.

FIGS. 7A and 7B also show that shape and materials selected to initiate the design greatly impact the sustainability of the final solution. For instance, initiating the design with any of the 3 HPCs mixes in the far-right corner greatly restrains the domain of available design solutions. In fact, the best solutions for these HPCs involve higher carbon footprints than any of the UHPC solutions in the far-right corner, even the least efficient ones. These findings highlight the importance of integrated optimization strategies in the early stages of the design process in order to achieve meaningful savings in carbon footprint.

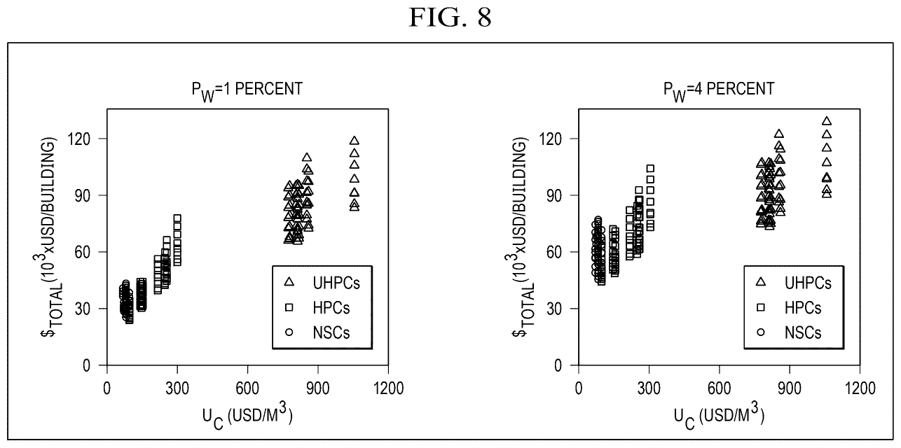

FIG. 8 is a diagram 800 that can be used to assess cost-efficiency of different concrete types in RC columns using the correlation between unit cost of concrete mix versus total cost of RC columns at two different reinforcement levels, in accordance with an example embodiment of the present disclosure. As shown in diagram 800, while there is a higher correlation between the unit cost of concrete mixtures and total material costs in RC columns, using concretes with low u_{c} does not necessarily lead to the most cost-efficient columns for the totality of the RC building. For instance, at a ρ_{ω}=4%, using an NSC mix that costs $85 USD/m³ could lead to a design that has a slightly higher total cost for the columns compared to a UHPC mix that costs $860 USD/m³.

The example workflow can guide the structural design process towards solutions that are both cost-effective and eco-friendly. For this example, optimum design solutions (i.e., with lowest impact values) and least-efficient solutions (i.e., with highest impact values) are detailed in Table A1 (Appendix) for each concrete class evaluated in this work.

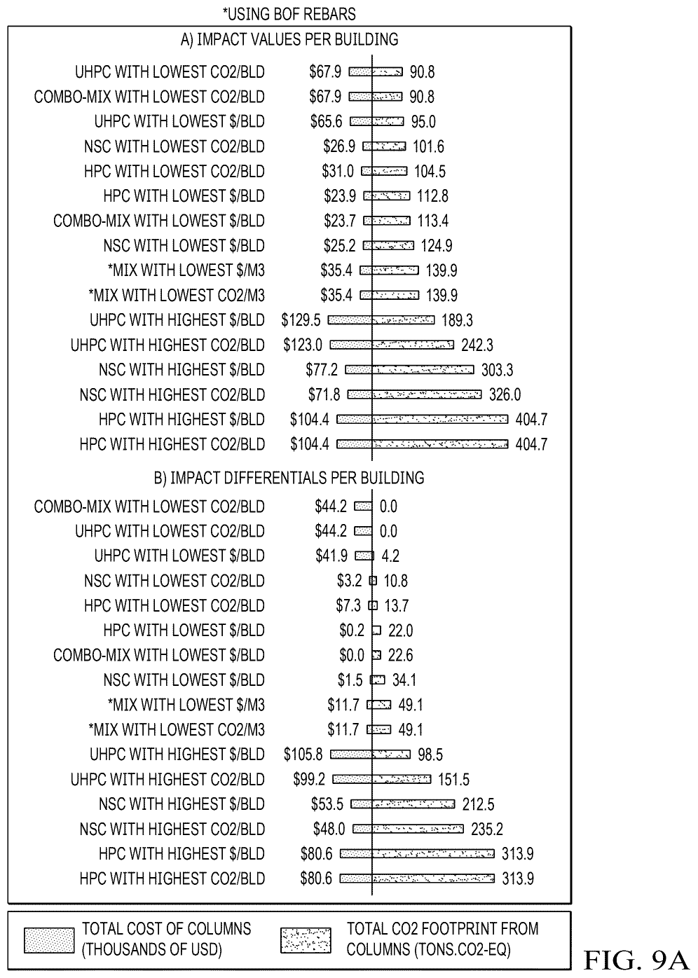

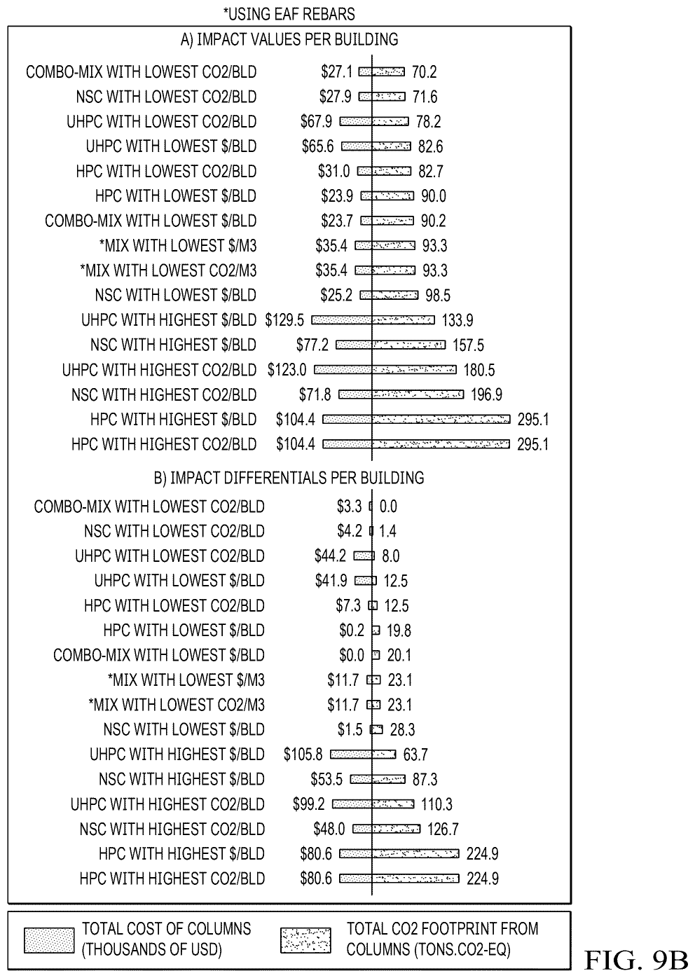

FIGS. 9A and 9B are diagrams that summarizes an optimum design solution, in accordance with an example embodiment of the present disclosure. Total cost and carbon footprint associated with casting all 288 columns on the 12-story building are plotted and show the large spectrum of values that the designer can achieve while considering all 1920 combinations available in this domain. On the other hand, impact differentials are also plotted. Impact differentials represent the difference between impact values measured for a given design solution and the value obtained for the solution in the domain with the lowest impact overall. In essence, impact differentials represent the cost and CO₂ in excess when setting the optimum solution in the domain as the baseline. FIGS. 9A and 9B thus demonstrates the savings that can be achieved in the building design just by optimizing the RC column system.

To discuss the magnitude of these savings, consider the lower plots from FIG. 9B corresponding to solutions that involve the use of EAF rebars. As it can be observed, initiating the design process with mix HPC-10 (HPC with the highest CO₂ per building) could lead to a column system with 225 tons.CO₂-eq in excess compared to the most eco-efficient solution in the domain. This solution is described in Table A1 as “combo-mix with the lowest CO₂/building” and consists in casting all columns in floors 1 and 2 with mix PLC-2, while casting all columns from floors 3 and above with mix HPC-4. In this case, saving 225 tons.CO₂-eq with this hybrid solution in lieu of mix HPC-10 represents savings of 76% in embodied CO₂. Moreover, the hybrid solution costs nearly 74% less than the solution involving mix HPC-10.

Perhaps a more viable solution from a constructability standpoint involves using the 2nd ranked solution (NSC with the lowest CO₂ per building), which consists in RC columns cast with mix PLC-2 across all floors. While this solution represents a 1% increase in total cost and CO₂ compared to the hybrid solution, it allows the interior columns to maintain a constant cross-section across the entire building (22×22 in²). This would eventually result in other cost savings related to labor time and formwork assemblage.

FIGS. 9A and 9B provide further evidence that selecting the mix with the lowest volumetric embodied CO₂ does not necessarily reduce the total embodied CO₂ of the building system. For instance, when EAF rebars are used, the mix with the lowest volumetric embodied CO₂, NSC-7 (i_{c}=268 kg.CO_{2-eq}/m³), produces 27% more CO₂ than mix NSC-2 (i_{c}=290 kg.CO_{2-eq}/m³) and 16% more CO₂ than mix UHPC-7 (UHPC with the lowest CO₂ per building), even though this mix has a volumetric GWP that is three times higher (i_{c}=836 kg.CO_{2-eq}/m³). In contrast with conventional expectations, the UHPC solutions evaluated in this work have shown that this class of concrete can be a viable solution for slender columns, not only for mid- and high-rise buildings, but also for low-rise buildings in regions where EAF rebars are scarce or unavailable.

In addition, observing all NSC mixtures in Table 4, only mix NSC-1 does not include partial replacements of OPC with SCMs. In reality, most of the concrete produced worldwide (especially in developing countries) reflect mix NSC-1 more so than the other low-carbon concretes evaluated in this work.

Findings discussed in this work highlight the importance of integrated optimization strategies supporting the structural design process to achieve meaningful savings in cost and carbon footprint for the totality of RC related projects. In addition, these results emphasize the need for environmental metrics in structural design to counteract the scarce availability of SCMs and EAF rebars at the global scale. This workflow can be used in the conceptual phase of projects, where rebar size and reinforcement layout are still undefined. Design recommendations obtained with this workflow can be used as drafts entering reinforcement detailing. Code specifications can be used to ensure that columns are safe from bending, shear, and torsional loads. Design factors involving multi-member interactions such as punching shear and drift are also excluded from the workflow due to their specificity and complexity (e.g., depending on structural system, seismic region, etc.). Nevertheless, this workflow can also be used at the very final stage of the design process, after defining the structural system and reinforcement detailing. At this stage, new constraints are defined for minimum area and reinforcement ratio needed to resist punching shear and bending moments, where the domain of available solutions becomes narrower compared to the one used in the conceptual stage.

This disclosure presents a design workflow for RC columns that incorporates cost and environmental considerations supporting the structural design process. Modifications to the ACI 318-19 building code are recommended to incorporate this workflow in conceptual stages of design (prior to reinforcement detailing) to help engineers and architects select the best combination of materials and column geometries that produces the floorplan with the least cost and embodied carbon footprint. This workflow also allows the user to refine material selection at the final stages of the design process. A dataset with 8 column types, 2 steel production routes, 4 levels of reinforcement ratios and 30 concrete mixtures from 3 different classes (UHPC, HPC and NSC) was assembled to evaluate nearly 2000 alternative designs for RC columns in a 12-story office building. Then, the proposed workflow was applied to this dataset to design RC columns that satisfy ACI 318-19 code requirements associated with crushing and buckling failure modes. The main conclusions drawn from this work include:

While optimization strategies in structural design have, historically, emphasized the minimization of steel content in RC members, results from this example embodiment show that decreasing the steel content alone does not minimize the embodied CO₂ of RC columns. An example supporting this claim was found when, for a fixed concrete grade, columns with ρ_{ω}=4% produced 12.5% less CO₂ compared to similar-shaped columns with ρ_{ω}=1%. In this case, the contribution of steel rebar to column capacity allowed the column to be designed with 42% less volume of concrete, which reduced the overall embodied CO₂ of the column.

Results suggest that the use of EAF rebars tend to produce columns with lower embodied CO₂ compared to using BOF rebars. However, results show that lowering the embodied CO₂ of the rebars alone does not guarantee designing the RC column with the lowest CO₂. In fact, several design solutions using BOF rebars outperformed design solutions using EAF rebars due to the synergistic effects of concrete strength, column shape and reinforcement ratio.

Results show that, even at volume fractions below 4%, the contribution of steel rebars to the embodied CO₂ of RC columns can, at times, surpass the contribution from concrete. For columns designed with BOF rebars, the ratio of steel-to-concrete related CO₂ emissions reached factors between 2 and 3 for several design solutions. The density of steel (7,821 kg/m³) and its embodied GWP (2.27 kg.CO₂-eq/kg for BOF rebars) produces a much higher volumetric GWP (17,754 kg.CO₂-eq/m³) compared to the concrete mixtures evaluated ([250-1200] kg.CO₂-eq/m³). Notably for concrete mix NSC-7, the carbon footprint associated with using one unit volume of steel surpassed the contributions from concrete by a factor of 66 for BOF rebars and a factor of 20 for EAF rebars.

In contrast to conventional wisdom, results show that decreasing binder content in concrete mixtures does not reduce the total carbon footprint of RC columns. No clear correlation was found between binder content and total carbon footprint, proving that eco-efficiency is independent of concrete type. In fact, ideal and nonideal solutions were obtained with all concrete technologies.

Results show that using concretes with low embodied CO₂ on a per-unit-volume basis does not lead to designing RC columns with the lowest overall carbon footprint. For instance, for designs involving EAF rebars, the mix with the lowest volumetric GWP (i_{c}=268 kg.CO₂-eq/m³) produced 16% more CO₂ than a mix with a volumetric GWP three times higher (i_{c}=836 kg.CO₂-eq/m³).

Optimizing shape and material selection in early design stages can greatly impact the sustainability of the final design. Initiating the design process with one pre-defined concrete mix can greatly restrain the optimization domain where, at times, the best design solutions obtained with a particular concrete mix can be far less efficient than even the worst design solution corresponding to a different concrete material.

Savings of approximately 76% in embodied CO₂ and 74% in material costs were obtained for the domain of concrete mixtures available by simply optimizing the column system. It is notable that these CO₂ savings far surpass the savings associated with cement replacement strategies that have been the focus of the industry in recent years. Considering that RC columns represent 5 to 10% of the total volume in RC buildings, these savings alone could represent approximately 4 to 8% for the entire structure. These findings highlight the importance of integrated optimization strategies in the early stages of the design process in order to achieve meaningful savings in carbon footprint for the totality of a project. In addition, these results emphasize the need for environmental metrics in structural design to counteract the scarce availability of SCMs and EAF rebars in many regions of the globe.

Similar methodologies can be used to optimize other structural members in RC buildings and, eventually, other RC applications. The process used to determine the eco-efficiency displayed by slender UHPC columns can be used for evaluation of the effects of alternative, less expensive fibers on flexural stiffness and ductility of RC columns. Further full-scale testing of slender UHPC columns can be used to evaluate whether adequate performance is obtained using, for instance, scrap tire recycled steel fibers or other non-metallic fibers, and may help make UHPC products more competitive for RC columns and expand its application.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes one or more microcomputers or other suitable data processing units, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections. The term “data” can refer to a suitable structure for using, conveying or storing data, such as a data field, a data buffer, a data message having the data value and sender/receiver address data, a control message having the data value and one or more operators that cause the receiving system or component to perform a function using the data, or other suitable hardware or software components for the electronic processing of data.

In general, a software system is a system that operates on a processor to perform predetermined functions in response to predetermined data fields. A software system is typically created as an algorithmic source code by a human programmer, and the source code algorithm is then compiled into a machine language algorithm with the source code algorithm functions, and linked to the specific input/output devices, dynamic link libraries and other specific hardware and software components of a processor, which converts the processor from a general purpose processor into a specific purpose processor. This well-known process for implementing an algorithm using a processor should require no explanation for one of even rudimentary skill in the art. For example, a system can be defined by the function it performs and the data fields that it performs the function on. As used herein, a NAME system, where NAME is typically the name of the general function that is performed by the system, refers to a software system that is configured to operate on a processor and to perform the disclosed function on the disclosed data fields. A system can receive one or more data inputs, such as data fields, user-entered data, control data in response to a user prompt or other suitable data, and can determine an action to take based on an algorithm, such as to proceed to a next algorithmic step if data is received, to repeat a prompt if data is not received, to perform a mathematical operation on two data fields, to sort or display data fields or to perform other suitable well-known algorithmic functions. Unless a specific algorithm is disclosed, then any suitable algorithm that would be known to one of skill in the art for performing the function using the associated data fields is contemplated as falling within the scope of the disclosure. For example, a message system that generates a message that includes a sender address field, a recipient address field and a message field would encompass software operating on a processor that can obtain the sender address field, recipient address field and message field from a suitable system or device of the processor, such as a buffer device or buffer system, can assemble the sender address field, recipient address field and message field into a suitable electronic message format (such as an electronic mail message, a TCP/IP message or any other suitable message format that has a sender address field, a recipient address field and message field), and can transmit the electronic message using electronic messaging systems and devices of the processor over a communications medium, such as a network. One of ordinary skill in the art would be able to provide the specific coding for a specific application based on the foregoing disclosure, which is intended to set forth exemplary embodiments of the present disclosure, and not to provide a tutorial for someone having less than ordinary skill in the art, such as someone who is unfamiliar with programming or processors in a suitable programming language. A specific algorithm for performing a function can be provided in a flow chart form or in other suitable formats, where the data fields and associated functions can be set forth in an exemplary order of operations, where the order can be rearranged as suitable and is not intended to be limiting unless explicitly stated to be limiting.

TABLE A1

| | | | GWP | | | |
|---|---|---|---|---|---|---|
| | | | (kg. | | | |
| | | | CO₂— | uc | | |
| Selected | Vertical | Mix | eq/ | (USD/ | | |
| solutions | group | Design | m3) | m3) | Interior columns | Exterior columns |
| Combo-mix | Floors | PLC-2 | 290 | 81 | 22 × 22 in² | 20 × 20 in² |
| w/lowest | 1st to | | | | slender column | slender column |
| CO₂/bld | 2nd | | | | w/ties | w/ties |
| | Floors | HPC-4 | 479 | 154 | 18 × 18 in² | 14 × 14 in² |
| | 3rd to | | | | slender column | slender column |
| | 12^{th} | | | | w/ties | w/ties |
| Combo-mix | Floors | NSC-5 | 450 | 82 | 22 × 22 in² | 20 × 20 in² |
| w/lowest | 1st to | | | | slender column | slender column |
| $/bld | 2nd | | | | w/ties | w/ties |
| | Floors | HPC-6 | 492 | 98 | 18 × 18 in² | 15 × 15 in² |
| | 3rd to | | | | slender column | slender column |
| | 12^{th} | | | | w/ties | w/ties |
| UHPC | Floors | UHPC-7 | 836 | 281 | 20 × 20 in² | 16 × 16 in² |
| w/lowest | 1st to | | | | slender column | slender column |
| CO₂/bld | 2nd | | | | w/ties | w/ties |
| | Floors | | | | 16 × 16 in² | 14 × 14 in² |
| | 3rd to | | | | slender column | slender column |
| | 12^{th} | | | | w/ties | w/ties |
| UHPC | Floors | UHPC-3 | 1179 | 303 | 34 x 18 in² | 30 × 14 in² |
| w/highest | 1st to | | | | slender column | slender column |
| CO₂/bld | 2nd | | | | w/ties | w/ties |
| | Floors | | | | 28 × 14 in² | 24 × 12 in² |
| | 3rd to | | | | slender column | slender column |
| | 12^{th} | | | | w/ties | w/ties |
| UHPC | Floors | UHPC-5 | 909 | 285 | 20 × 20 in² | 16 × 16 in² |
| w/lowest | 1st to | | | | slender column | slender column |
| $/bld | 2nd | | | | w/ties | w/ties |
| | Floors | | | | 16 × 16 in² | 14 × 14 in² |
| | 3rd to | | | | slender column | slender column |
| | 12^{th} | | | | w/ties | w/ties |
| UHPC | Floors | UHPC-4 | 926 | 514 | 32 × 16 in² | 28 × 14 in² |
| w/highest | 1st to | | | | slender column | slender column |
| $/bld | 2nd | | | | w/ties | w/ties |
| | Floors | | | | 26 × 14 in² | 24 × 12 in² |
| | 3rd to | | | | slender column | slender column |
| | 12^{th} | | | | w/ties | w/ties |
| HPC | Floors | HPC-4 | 479 | 154 | 20 × 20 in² | 18 × 18 in² |
| w/lowest | 1st to | | | | slender column | slender column |
| CO₂/bld | 2nd | | | | w/ties | w/ties |
| | Floors | | | | 18 × 18 in² | 14 × 14 in² |
| | 3rd to | | | | slender column | slender column |
| | 12^{th} | | | | w/ties | w/ties |
| HPC | Floors | HPC-10 | 1128 | 303 | 34 × 18 in² | 30 × 16 in² |
| w/highest | 1st to | | | | slender column | slender column |
| CO₂/bld | 2nd | | | | w/ties | w/ties |
| | Floors | | | | 30 × 14 in² | 26 × 12 in² |
| | 3rd to | | | | slender column | slender column |
| | 12^{th} | | | | w/ties | w/ties |
| HPC | Floors | HPC-6 | 492 | 98 | 22 × 22 in² | 18 × 18 in² |
| w/lowest | 1st to | | | | slender column | slender column |
| $/bld | 2nd | | | | w/ties | w/ties |
| | Floors | | | | 18 × 18 in² | 16 × 16 in² |
| | 3rd to | | | | slender column | slender column |
| | 12^{th} | | | | w/ties | w/ties |
| HPC | Floors | HPC-10 | 1128 | 303 | 34 × 18 in² | 30 × 16 in² |
| w/highest | 1st to | | | | slender column | slender column |
| $/bld | 2nd | | | | w/ties | w/ties |
| | Floors | | | | 30 × 14 in² | 26 × 12 in² |
| | 3rd to | | | | slender column | slender column |
| | 12^{th} | | | | w/ties | w/ties |
| NSC | Floors | PLC-2 | 290 | 81 | 22 × 22 in² | 20 x 20 in² |
| w/lowest | 1st to | | | | slender column | slender column |
| CO₂/bld | 2nd | | | | w/ties | w/ties |
| | Floors | | | | 22 × 22 in² | 16 × 16 in² |
| | 3rd to | | | | slender column | slender column |
| | 12^{th} | | | | w/ties | w/ties |
| NSC | Floors | NSC-1 | 515 | 96 | 138 × 20 in² | 32 × 16 in² |
| w/highest | 1st to | | | | slender column | slender column |
| CO₂/bld | 2nd | | | | w/ties | w/ties |
| | Floors | | | | 32 × 16 in² | 28 × 14 in² |
| | 3rd to | | | | slender column | slender column |
| | 12^{th} | | | | w/ties | w/ties |
| NSC | Floors | NSC-5 | 450 | 82 | 22 × 22 in² | 20 × 20 in² |
| w/lowest | 1st to | | | | slender column | slender column |
| $/bld | 2nd | | | | w/ties | w/ties |
| | Floors | | | | 20 x 20 in² | 16 × 16 in² |
| | 3rd to | | | | slender column | slender column |
| | 12^{th} | | | | w/ties | w/ties |
| NSC | Floors | NSC-4 | 288 | 83 | 40 × 20 in² | 36 × 18 in² |
| w/highest | 1st to | | | | slender column | slender column |
| $/bld | 2nd | | | | w/ties | w/ties |
| | Floors | | | | 34 × 18 in² | 30 × 14 in² |
| | 3rd to | | | | slender column | slender column |
| | 12^{th} | | | | w/ties | w/ties |
| Mix | Floors | NSC-7 | 268 | 71 | 32 in short | 24 in short |
| w/lowest | 1st to | | | | circular column | circular column |
| CO₂/m3 | 2nd | | | | w/spiral | w/spiral |
| | Floors | | | | 30 in short | 20 in short |
| | 3rd to | | | | circular column | circular column |
| | 12^{th} | | | | w/spiral | w/spiral |
| Mix | Floors | NSC-7 | 268 | 71 | 32 in short | 24 in short |
| w/lowest | 1st to | | | | circular column | circular column |
| $/m3 | 2nd | | | | w/spiral | w/spiral |
| | Floors | | | | 30 in short | 20 in short |
| | 3rd to | | | | circular column | circular column |
| | 12^{th} | | | | w/spiral | w/spiral |

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A method for manufacturing and fabricating structural components, comprising:
loading one or more instructions into a data memory device of a processor that cause the processor to perform the steps of:
generating a gross area limit metric and a gross area minimum metric for predetermined boundary conditions for a structural component;
generating a gross area short metric and a gross area long metric for a plurality of available materials for the structural component;
setting the gross area minimum metric to the gross area short metric if it is determined that the gross area short metric is not greater than the gross area minimum metric; and
fabricating the structural component using the gross area minimum metric.

2. The method of claim 1 further comprising:
setting a gross area trial metric to the gross area short metric if it is determined that the gross area short metric is greater than the gross area limit metric; and
fabricating the structural component using the gross area trial metric.

3. The method of claim 1 wherein the gross area limit metric comprises a gross column area limit metric.

4. The method of claim 1 wherein the gross area minimum metric comprises a gross column area minimum metric.

5. The method of claim 1 wherein the gross area short metric comprises a gross column area short metric.

6. The method of claim 1 wherein the gross area long metric comprises a gross column area long metric.

7. The method of claim 2 wherein the gross area trial metric comprises a gross column area trial metric.

8. The method of claim 1 further comprising setting the gross area minimum metric to the gross area long metric if the gross area long metric is greater than the gross area minimum metric.

9. The method of claim 2 further comprising setting the gross area long metric to the gross area trial metric if the gross area long metric is greater than the gross area minimum metric.

10. A structural component comprising:
a concrete component having a first carbon dioxide metric;
an iron component having a second carbon dioxide metric;
a combined minimum concrete and iron structural metric; and
wherein structural parameters of a combination of the concrete component and the iron component are selected to minimize a sum of the first carbon dioxide metric and the second carbon dioxide metric without causing the combined structural parameters to fall below a predetermined minimum.

11. The structural component of claim 10 manufactured using a method, comprising:
loading one or more instructions into a data memory device of a processor that cause the processor to perform the steps of:
generating a gross area limit metric and a gross area minimum metric for predetermined boundary conditions for a structural component;
generating a gross area short metric and a gross area long metric for a plurality of available materials for the structural component;
setting the gross area minimum metric to the gross area short metric if it is determined that the gross area short metric is not greater than the gross area minimum metric; and
fabricating the structural component using the gross area minimum metric.

12. The structural component of claim 11 wherein the method further comprises:
setting a gross area trial metric to the gross area short metric if it is determined that the gross area short metric is greater than the gross area limit metric; and
fabricating the structural component using the gross area trial metric.

13. The structural component of claim 11 wherein the gross area limit metric comprises a gross column area limit metric.

14. The structural component of claim 11 wherein the gross area minimum metric comprises a gross column area minimum metric.

15. The structural component of claim 11 wherein the gross area short metric comprises a gross column area short metric.

16. The structural component of claim 11 wherein the gross area long metric comprises a gross column area long metric.

17. The structural component of claim 11 wherein the gross area trial metric comprises a gross column area trial metric.

18. The structural component of claim 11 wherein the method further comprises setting the gross area minimum metric to the gross area long metric if the gross area long metric is greater than the gross area minimum metric.

19. The structural component of claim 11 wherein the method further comprises setting the gross area long metric to the gross area trial metric if the gross area long metric is greater than the gross area minimum metric.
